(19) United States
(12) Patent Application Publication
(10) Pub. No.: US 2026/0101640 A1
(43) Pub. Date: Apr. 9, 2026

(54) DISPLAY DEVICE

(71) Applicant: LG Display Co., Ltd., Seoul (KR)

(72) Inventors: Byunggwan HYUN, Paju-si (KR); Seungbum LEE, Paju-si (KR); Younghoon KIM, Paju-si (KR)

(73) Assignee: LG Display Co., Ltd., Seoul (KR)

(21) Appl. No.: 19/086,977

(22) Filed: Mar. 21, 2025

(30) Foreign Application Priority Data
Oct. 7, 2024 (KR) 10-2024-0135413

(51) Int. Cl. H10K 59/122; H10D 86/40; H10D 86/60; H10K 59/121; H10K 59/19; H10K 59/38; H10K 59/40; H10K 59/80; H10K 102/00

(52) U.S. Cl. CPC H10K 59/122; H10K 59/1213; H10K 59/19; H10K 59/38; H10K 59/8792; H10D 86/421; H10D 86/60; H10K 59/40; H10K 2102/331

(57) ABSTRACT

A display device according to an embodiment includes a substrate, a display area including a plurality of sub-pixels, a non-display area outside the display area, a first electrode arranged on the substrate for each of the sub-pixels, a first bank arranged on the first electrode, located at a boundary between adjacent sub-pixels, and overlapping a peripheral region of an upper surface of the first electrode, and a plurality of nanostructures disposed on an upper surface of the first bank.

### CROSS REFERENCE TO RELATED APPLICATION

The present application claims the benefit of and priority to Korean Patent Application No. 10-2024-0135413, filed on Oct. 7, 2024, the entire contents of which are incorporated herein by reference for all purposes.

### BACKGROUND

### 1. Technical Field

The present disclosure relates to a display device.

### 2. Description of the Related Art

With the advancement of the information society, there is an increasing demand for display devices that can show images, and various types of display devices such as liquid crystal display (LCD) devices and organic light emitting diode (OLED) displays are being utilized.

The display device includes a plurality of pixels and is equipped with a plurality of switching elements to drive and control the pixels.

The description of the related art should not be assumed to be prior art merely because it is mentioned in or associated with this section. The description of the related art includes information that describes one or more aspects of the subject technology, and the description in this section does not limit the invention.

### SUMMARY

The embodiments of this present disclosure aim to provide a display device capable of absorbing external light to reduce surface reflection caused by external light.

The embodiments of this present disclosure aim to provide a display device that enhances power efficiency by achieving low reflectivity through the reduction of surface reflection from external light.

The aspects of this present disclosure are not limited to those mentioned above, and other technical aspects may be inferred from the following embodiments.

In order to accomplish the above aspects, a display device according to an embodiment includes a substrate, a display area including a plurality of sub-pixels, a non-display area outside the display area, a first electrode arranged on the substrate for each of the sub-pixels, a first bank arranged on the first electrode, located at a boundary between adjacent sub-pixels, and overlapping a peripheral region of an upper surface of the first electrode, and a plurality of nanostructures disposed on an upper surface of the first bank.

In order to accomplish the above aspects, a display device according to another embodiment includes a substrate, a display area including a plurality of sub-pixels, a non-display area outside the display area, a first electrode arranged on the substrate for each of the sub-pixels, a first bank arranged on the first electrode, located at a boundary between adjacent sub-pixels, and overlapping a peripheral region of an upper surface of the first electrode, and a plurality of nanostructures on the first bank, wherein the plurality of nanostructures have a tilt angle equal to or less than 30 degrees with respect to a front of the display device, scattering or reflecting light incident on the front and dissipating the light.

The specific details of other embodiments are included in the detailed description and drawings.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a plan view of a display device according to an embodiment;

FIG. 2 is a cross-sectional view of the display panel of FIG. 1 in a bent state;

FIG. 3 is a cross-sectional view taken along line A-A′ of FIG. 1;

FIG. 4 is a detailed cross-sectional view of the light-emitting layer of FIG. 3;

FIG. 5 is a detailed cross-sectional view of the light-emitting layer according to an alternative embodiment;

FIG. 6 is a cross-sectional view of the touch layer according to FIG. 3;

FIG. 7 is a cross-sectional view taken along line B-B′ of FIG. 1;

FIG. 8 is a cross-sectional view taken along line C-C′ of FIG. 1;

FIG. 9 is an enlarged cross-sectional view of the Q1 area of FIG. 3;

FIG. 10 is an enlarged cross-sectional view of the Q2 area of FIG. 9;

FIGS. 11 to 14 are cross-sectional views illustrating the process steps of a manufacturing method for a display panel according to an embodiment;

FIG. 15 is a graph illustrating light reflectivity according to the inclination of nanostructures according to an embodiment;

FIG. 16 is a cross-sectional view of a display device according to another embodiment;

FIG. 17 is a cross-sectional view of a display device according to another embodiment;

FIG. 18 is a cross-sectional view of a display device according to another embodiment;

FIG. 19 is a cross-sectional view of a display device according to another embodiment;

FIG. 20 is a cross-sectional view of a display device according to another embodiment;

FIG. 21 is a perspective view of a display device according to another embodiment; and

FIG. 22 is a cross-sectional view taken along line D-D′ of FIG. 21.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, embodiments will be described with reference to accompanying drawings.

The same reference numerals refer to the same components. Additionally, in the drawings, the thickness, proportions, and dimensions of components may be exaggerated for effective explanation of the technical content. Although depicted in a scale different from their actual scale for the convenience of explanation, the components are not limited to the scale shown in the drawing.

In this present disclosure, when a component (or area, layer, part, etc.) is mentioned as being “on top of,” “connected to,” or “coupled to” another component, it means that it may be directly connected/coupled to the other component, or a third component may be placed between them.

The expression “and/or” is taken to include one or more combinations that can be defined by associated components.

The terms “first,” “second,” etc. are used to describe various components, but the components should not be limited by these terms. The terms are used only for distinguishing one component from another component. For example, a first component may be referred to as a second component and, similarly, the second component may be referred to as the first component, without departing from the scope of the present invention. The singular forms are intended to include the plural forms as well unless the context clearly indicates otherwise.

The terms such as “below,” “lower,” “above,” “upper,” etc. are used to describe the relationship of components depicted in the drawings. The terms are relative concepts and are described based on the direction indicated on the drawing. For example, unless explicitly stated with terms such as “directly” or “immediately,” one or more other components may be positioned between two described components. Spatially relative terms such as “below,” “beneath,” “lower,” “above,” and “upper” may be used to facilitate the description of the relationship between one component or element and another, as illustrated in the drawings. These spatially relative terms should be understood to include different orientations of a component during use or operation, in addition to the orientation shown in the drawings. For instance, if a component shown in the drawings is flipped, a component described as being “below” or “beneath” another component may then be positioned “above” that component. Accordingly, the term “below,” for example, may encompass both upward and downward directions.

It will be further understood that the terms “comprise,” “include,” “contain, ” “have,” “constitute,” “made of,” “formed of,” “composed of,” and the like are intended to specify the presence of stated features, numbers, steps, operations, components, parts, or a combination thereof but are not intended to preclude the presence or possibility of one or more other features, numbers, steps, operations, components, parts, or combinations thereof.

The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can. ” The various features of the embodiments of the disclosure can combined or assembled together, either partially or entirely, in a technically diverse manner, and each embodiment can be independently implemented or in conjunction with related embodiments.

Hereinafter, the display devices according to the embodiments of this present disclosure will be described with reference to the accompanying drawings.

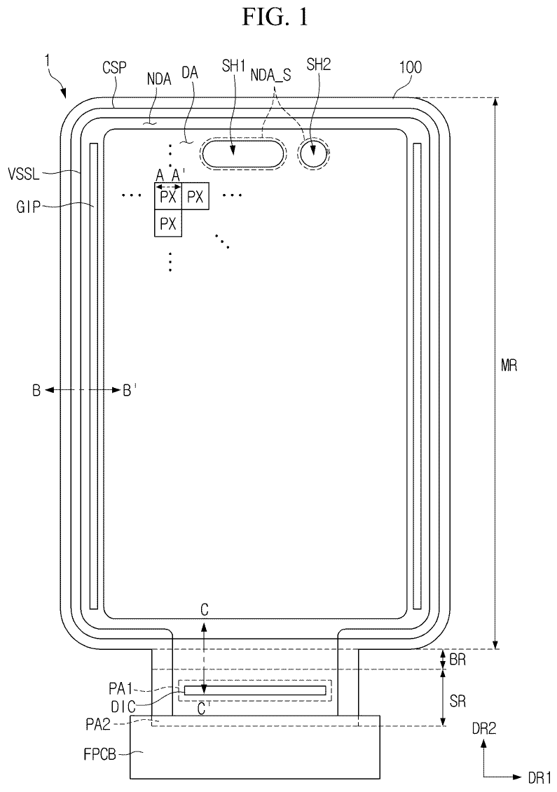

FIG. 1 is a plan view of a display device according to an embodiment.

Referring to FIG. 1, a display device 1 according to an embodiment may include a display panel 100. The display panel 100 may include a display area DA including a plurality of pixels PX and a non-display area NDA surrounding the display area DA. The display area DA may have a rectangular planar shape. However, the display area DA is not limited thereto and may have a square, circular, elliptical, or other polygonal planar shape. For example, the display area DA may have a rounded rectangular shape, but it is not limited thereto and may also be a rectangular shape with sharp corners.

In the embodiments, a first direction DR1 and a second direction DR2 are different directions that intersect each other, such as directions perpendicular to each other in a plan view. In FIG. 1, the first direction DR1 may correspond to the extending direction of the short sides of the display panel 100, while the second direction DR2 may correspond to the extending direction of the long sides of the display panel 100. However, it should be understood that the directions mentioned in the embodiments are relative and are not limited to the specific directions described.

The display area DA may include short sides extending along the first direction DR1 and long sides extending along the second direction DR2. The non-display area NDA may surround the display area DA. The non-display area NDA may be disposed on one side and the other side of the display area DA in the first direction DR1 and on one side and the other side of the display area DA in the second direction DR2.

The display panel 100 may further include sensor non-display areas NDA_S and sensor holes SH surrounded by the sensor non-display areas NDA_S. The sensor holes SH1 and SH2 may be surrounded by the display area DA in a plan view. The sensor holes SH1 and SH2 may, for example, be two in number as shown in FIG. 1, but the embodiments of this present disclosure are not limited thereto. For example, a single sensor hole may be provided. The two sensor holes SH1 and SH2 may be provided for the arrangement of an infrared sensor and a camera sensor, respectively; however, the embodiments of this present disclosure are not limited to this configuration. The sensor non-display area NDA_S may be disposed between the sensor holes SH1 and SH2 and the display area DA. The sensor non-display area NDA_S may completely surround the sensor holes SH1 and SH2. No pixels PX may be arranged in the sensor non-display area NDA_S.

A gate driving unit GIP may be arranged in the non-display area NDA located on each of one side and the other side of the display area DA in the first direction DR1. A low-potential voltage line VSSL may be disposed outside the gate driving unit GIP in the non-display area NDA. For example, as shown in FIG. 1, the low-potential voltage line VSSL may extend from a flexible printed circuit board FPCB, pass through a sub-region SR and a bending region BR, and be positioned outside the gate driving unit GIP in the non-display area NDA while surrounding the display area DA.

The non-display area NDA located on the opposite side of the display area DA in the second direction DR2 may extend further in the second direction DR2 from the central portion of that side of the display area DA. The width in the first direction DR1 of the non-display area NDA, which extends further in the second direction DR2 from the central portion of the opposite side of the display area DA in the second direction DR2, may be smaller than the width in the first direction DR1 of the non-display area NDA adjacent to the opposite side of the display area DA in the second direction DR2.

The display device 1 may include a main region MR, a sub-region SR, and a bending region BR between the main region MR and the sub-region SR. The display area DA and the non-display area NDA surrounding the display area DA on all four sides may form the main region MR, while the portion extending further in the second direction DR2 from the central portion of the other side of the display area DA may constitute the bending region BR and the sub-region SR. The bending region BR may be positioned between the sub-region SR and the main region MR. The sub-region SR may include a first pad area PA1 and a second pad area PA2 located at the opposite end of the sub-region SR in the second direction DR2. The display device 1 may further include a data driving unit DIC and a flexible printed circuit board FPCB. The data driving unit DIC may be placed in the first pad area PA1, and the flexible printed circuit board FPCB may be attached to the second pad area PA2. The first pad area PA1 and the second pad area PA2 may each include a number of pads that connect the data driving unit DIC and the flexible printed circuit board FPCB. The data driving unit DIC may, for example, be provided in the form of a driving chip IC, but is not limited thereto. In an embodiment, the data driving unit DIC is arranged in a chip-on-plastic method, directly mounted on the display panel 100, but is not limited thereto, and may also be arranged in a chip-on-glass or chip-on-film method.

The display panel 100 according to an embodiment may further include a crack detection pattern CSP surrounding the low-potential voltage line VSSL. The crack detection pattern CSP may be arranged to completely surround the display area DA, as shown in FIG. 1. For example, the crack detection pattern CSP may be placed on the outer side of the low-potential voltage line VSSL. However, the embodiments of this present disclosure are not limited thereto, and the crack detection pattern CSP may not be partially disposed in the non-display area NDA on the opposite side of the display area DA in the second direction DR2.

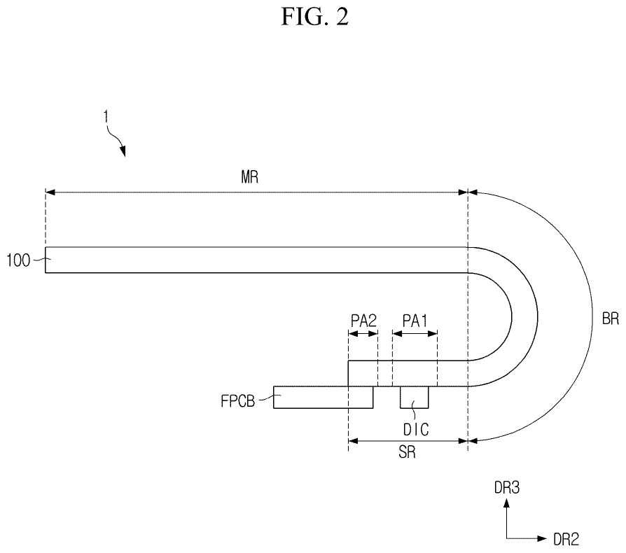

FIG. 2 is a cross-sectional view of the display panel of FIG. 1 in a bent state.

Referring to FIG. 2, the bending region BR of the display panel 100 of the display device 1 according to an embodiment may be bent in the thickness direction (or the third direction DR3). Through this, the main region MR and the sub-region SR may overlap in the thickness direction. The display panel 100 may be bent such that the bottom surface of the main region MR and the top surface of the sub-region SR face each other. A flexible printed circuit board FPCB may be attached to the end of the sub-region SR.

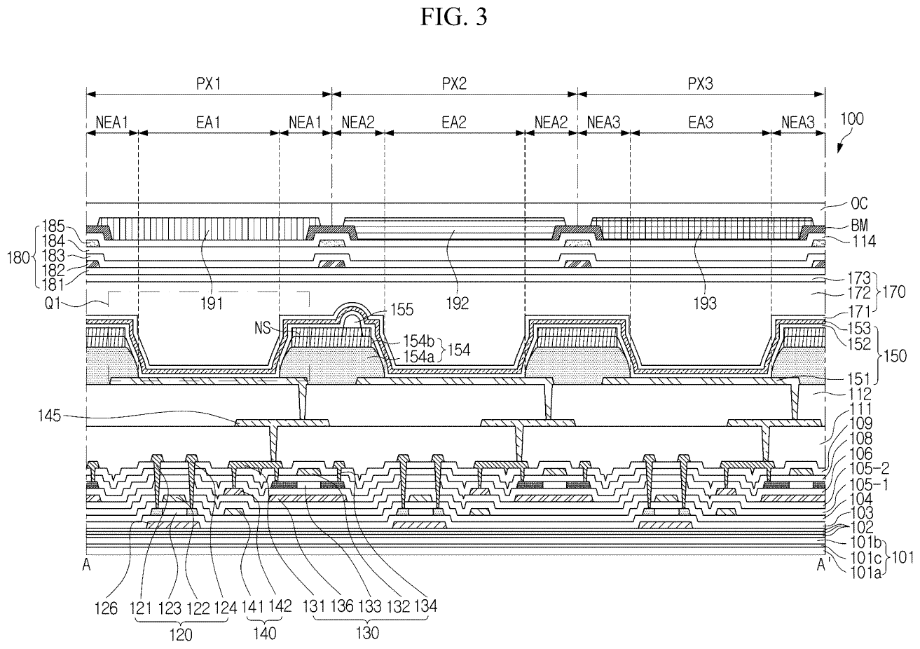

FIG. 3 is a cross-sectional view taken along line A-A′ of FIG. 1.

Referring to FIG. 3, the pixel PX (see FIG. 1) of the display panel 100 may include a plurality of sub-pixels PX1, PX2, and PX3. The first sub-pixel PX1 may be a red sub-pixel, the second sub-pixel PX2 may be a green sub-pixel, and the third sub-pixel PX3 may be a blue sub-pixel, but the embodiments of this present disclosure are not limited thereto. In some embodiments, the pixel PX may further include a fourth sub-pixel, which may be a white sub-pixel, but the embodiments of this present disclosure are not limited thereto. In some embodiments, the pixel PX may include one red sub-pixel, two green sub-pixels, and one blue sub-pixel, but the embodiments of this present disclosure are not limited thereto. For example, a plurality of sub-pixels PX1, PX2, and PX3 may be arranged in a stripe arrangement along the first direction DR1, but are not limited thereto and may also be arranged in a pentile arrangement.

The display panel 100 may include a substrate 101, a first thin-film transistor 120, a second thin-film transistor 130, a light-emitting layer 150, an encapsulation layer 170, a touch layer 180, a filter insulating layer 114, a black matrix BM, color filters 191, 192, and 193, and a planarization layer OC. The display panel 100 may include at least one panel insulating layer between the substrate 101 and the light-emitting layer 150, and at least one touch insulating layer. The at least one panel insulating layer may include at least one of a buffer layer 102, a first insulating layer 103, a second insulating layer 104, a third-1 insulating layer 105-1, a third-2 insulating layer 105-2, a fourth insulating layer 106, a fifth insulating layer 108, a sixth insulating layer 109, a first protective layer 111, and a second protective layer 112, and the at least one touch insulating layer may include at least one of a touch buffer layer 181, a first touch insulating layer 183, and a second touch insulating layer 184.

The substrate 101 may include one or more plastic materials. For example, the substrate 101 may be a multi-substrate including a plurality of plastic materials, such as polyimide. For example, the substrate 101 may include a first substrate portion 101a and a second substrate portion 101b, each including a plastic material, and a third substrate portion 101c, which includes an inorganic insulating material between the first and second substrate portions 101a and 101b, but the embodiments of this present disclosure are not limited thereto.

A buffer layer 102 may be disposed on the substrate 101. The buffer layer 102 may minimize or delay the diffusion of moisture or oxygen that penetrates into the substrate 101. The buffer layer 102 may be formed by alternately stacking silicon nitride (SiNx) and silicon oxide (SiOx) at least once, but the embodiments of this present disclosure are not limited thereto.

A first light-blocking layer 126 may be disposed on the buffer layer 102. The first light-blocking layer 126 may prevent light from passing through the first semiconductor layer 123 of the first thin-film transistor 120. For example, the first semiconductor layer 123 may be disposed to overlap with the first light-blocking layer 126. The first light-blocking layer 126 may be a single layer or multiple layers made of molybdenum (Mo), aluminum (Al), chromium (Cr), nickel (Ni), neodymium (Nd), copper (Cu), or any of their alloys, but the embodiments of this present disclosure are not limited thereto.

A first insulating layer 103 may be disposed on the buffer layer 102 and the first light-blocking layer 126. The first insulating layer 103 may prevent a short circuit between the configuration of the first thin-film transistor 120 and the first light-blocking layer 126. The first insulating layer 103 may be made of the same material as the buffer layer 102, but the embodiments of this present disclosure are not limited thereto. For example, the first insulating layer 103 may be made of an inorganic insulating material, such as silicon nitride (SiNx) or silicon oxide (SiOx), but the embodiments of this present disclosure are not limited thereto.

A first thin-film transistor 120 may be disposed on the first insulating layer 103. The first thin-film transistor 120 may include a first source electrode 121, a first gate electrode 122, a first semiconductor layer 123, and a first drain electrode 124.

The first semiconductor layer 123 may be disposed on the first insulating layer 103. The first semiconductor layer 123 may include a metal oxide semiconductor such as Indium-Gallium-Zinc Oxide (IGZO), or a silicon-based semiconductor material such as amorphous silicon or polycrystalline silicon, but the embodiments of this present disclosure are not limited thereto. The first semiconductor layer 123 may include a channel region, a source region, and a drain region.

The polycrystalline semiconductor layer has higher mobility than the amorphous semiconductor layer and the oxide semiconductor layer, so it may have lower power consumption and improved reliability. Therefore, the driving transistor may be formed using a polycrystalline semiconductor layer.

A second insulating layer 104 may be disposed on the first semiconductor layer 123. The second insulating layer 104 may be made of the same material as the first insulating layer 103 and may prevent short circuits between the first semiconductor layer 123 and other components of the first thin-film transistor 120.

A first gate electrode 122 may be disposed on the second insulating layer 104. The first gate electrode 122 may be arranged to overlap with the channel region of the first semiconductor layer 123, positioned on the second insulating layer 104. The first gate electrode 122 may be composed of a single layer or multilayer structure that includes materials such as molybdenum (Mo), copper (Cu), titanium (Ti), aluminum (Al), chromium (Cr), gold (Au), nickel (Ni), neodymium (Nd), or their compounds, but the embodiments of this present disclosure are not limited to these materials. The first gate electrode 122 may be arranged along with a gate line.

Third insulating layers 105-1 and 105-2 may be disposed on the first gate electrode 122. The third insulating layers 105-1 and 105-2 may be formed by alternating layers of silicon nitride (SiNx) and silicon oxide (SiOx) at least once, but the embodiments of this present disclosure are not limited thereto. For example, the third-1 insulating layer 105-1 may include silicon oxide (SiOx), and the third-2 insulating layer 105-2 may include silicon nitride (SiNx), but the embodiments of this present disclosure are not limited thereto.

The first source electrode 121 and the first drain electrode 124 may be disposed on the third insulating layers 105-1 and 105-2.

The first source electrode 121 and the first drain electrode 124 may be electrically connected to the first semiconductor layer 123 through contact holes. The first source electrode 121 and the first drain electrode 124 may be made of a metal material. For example, the first source electrode 121 and the first drain electrode 124 may be composed of a single layer or multiple layers made of any one of molybdenum (Mo), aluminum (Al), chromium (Cr), gold (Au), titanium (Ti), nickel (Ni), neodymium (Nd), copper (Cu), or their alloys, but the embodiments of this present disclosure are not limited thereto.

The first source electrode 121 and the first drain electrode 124 may be arranged along with the data line. For example, the data line may be formed in the same layer and made of the same material as the first source electrode 121 and the first drain electrode 124, but the embodiments of this present disclosure are not limited thereto.

The storage electrode 140 may be disposed apart from the first thin-film transistor 120. The storage electrode 140 may include a first storage electrode 141 and a second storage electrode 142.

The first storage electrode 141 may be disposed in the same layer and made of the same material as the first gate electrode 122, but the embodiments of this present disclosure are not limited thereto.

The second storage electrode 142 may be disposed on the first storage electrode 141. The second storage electrode 142 may be disposed on the third insulating layers 105-1 and 105-2, and a capacitance may be formed between the first storage electrode 141 and the second storage electrode 142 with the third insulating layers 105-1 and 105-2 acting as a dielectric. The second storage electrode 142 may be made of the same material as the first storage electrode 141, but the embodiments of this present disclosure are not limited thereto.

The second thin-film transistor 130 may be disposed spaced apart from the first thin-film transistor 120 and the storage electrode 140. The second thin-film transistor 130 may include a second source electrode 131, a second gate electrode 132, a second semiconductor layer 133, and a second drain electrode 134.

The second light-blocking layer 136 may be disposed in the same layer as the second storage electrode 142.

The second light-blocking layer 136, similar to the first light-blocking layer 126, may prevent light from reaching the second semiconductor layer 133, thereby extending the lifespan of the second thin-film transistor 130. For example, the second semiconductor layer 133 may be disposed overlapping with the second light-blocking layer 136.

The fourth insulating layer 106 may be disposed on the second light-blocking layer 136. The fourth insulating layer 106 may be made of the same material as the first insulating layer 103, the second insulating layer 104, or the third insulating layer 105-1 and 105-2, but the embodiments of this present disclosure are not limited thereto.

The second semiconductor layer 133 may be disposed on the fourth insulating layer 106. The second semiconductor layer 133 may include a source region, a drain region, and a channel region between the source and drain regions.

The second semiconductor layer 133 may include a semiconductor material such as a metal oxide semiconductor like Indium-Gallium-Zinc Oxide (IGZO), or a silicon-based semiconductor material such as amorphous silicon or polycrystalline silicon, but the embodiments of this present disclosure are not limited thereto.

The fifth insulating layer 108 may be disposed on the second semiconductor layer 133. The fifth insulating layer 108 may be made of the same material as the first insulating layer 103, the second insulating layer 104, the third insulating layer 105-1 and 105-2, or the fourth insulating layer 106, but the embodiments of this present disclosure are not limited thereto.

The second gate electrode 132 may be disposed on the fifth insulating layer 108.

The second gate electrode 132 may be made of the same material as the first gate electrode 122. For example, the second gate electrode 132 may be formed as a single layer or multiple layers made from materials such as molybdenum (Mo), copper (Cu), titanium (Ti), aluminum (Al), chromium (Cr), gold (Au), nickel (Ni), neodymium (Nd), or alloys of these materials, but the embodiments of this present disclosure are not limited thereto.

The sixth insulating layer 109 may be disposed on the second gate electrode 132. The sixth insulating layer 109 may be made of the same material as the first insulating layer 103, second insulating layer 104, third insulating layer 105-1 and 105-2, fourth insulating layer 106, or fifth insulating layer 108, but the embodiments of this present disclosure are not limited thereto.

The first source electrode 121, first drain electrode 124, second source electrode 131, and second drain electrode 134 may be disposed on the sixth insulating layer 109.

The second source electrode 131 and second drain electrode 134 may be made of the same material as the first source electrode 121 and first drain electrode 124 and may be disposed in the same layer, but the embodiments of this present disclosure are not limited thereto. For example, the second source electrode 131 and second drain electrode 134 may be formed as a single layer or multiple layers made from materials such as molybdenum (Mo), aluminum (Al), chromium (Cr), gold (Au), titanium (Ti), nickel (Ni), neodymium (Nd), and copper (Cu) or alloys of these materials, but the embodiments of this present disclosure are not limited thereto. For example, the second source electrode 131 may be electrically connected to the second storage electrode 142. The second source electrode 131 may be electrically connected to the second storage electrode 142 by passing through the sixth insulating layer 109, fifth insulating layer 108, and fourth insulating layer 106.

The first thin-film transistor 120 may be a driving transistor, and the second thin-film transistor 130 may be a switching transistor, but the embodiments of this present disclosure are not limited thereto.

The first source electrode 121 and the first drain electrode 124 may have a first protective layer 111 disposed thereon.

The first protective layer 111 may flatten the upper part of the first thin-film transistor 120 and protect the first thin-film transistor 120. The first protective layer 111 may be made of an organic material. For example, the first protective layer 111 may be made of an organic material such as acrylic resin, epoxy resin, phenolic resin, polyamide resin, or polyimide resin, but the embodiments of this present disclosure are not limited thereto.

The second protective layer 112 may be disposed on the first protective layer 111. The second protective layer 112 may be formed of the same material as the first protective layer 111, but the embodiments of this present disclosure are not limited thereto.

In some embodiments, a third protective layer may be further disposed on the upper surface of the second protective layer 113, but the embodiments of this present disclosure are not limited thereto.

A connection electrode 145 may be disposed between the first protective layer 111 and the second protective layer 112.

The connection electrode 145 may electrically connect the first thin-film transistor 120 and the light-emitting layer 150. The connection electrode 145 may be made of the same material as the first source electrode 121 and the first drain electrode 124, but the embodiments of this present disclosure are not limited thereto.

The connection electrode 145 may be a single layer or multilayer made from materials such as molybdenum (Mo), aluminum (Al), chromium (Cr), gold (Au), titanium (Ti), nickel (Ni), neodymium (Nd), and copper (Cu) or alloys of these materials, but the embodiments of this present disclosure are not limited thereto.

The light-emitting layer 150 may be disposed on the second protective layer 112. The light-emitting layer 150 may include a first electrode 151, an organic layer 152, and a second electrode 153. The first electrode 151 may function as the anode, and the second electrode 153 may function as the cathode. The first electrode 151 may be disposed on the second protective layer 112. The first electrode 151 may be electrically connected to the first thin-film transistor 120 through a contact hole formed in the second protective layer 112. The first electrode 151 may be a reflective electrode that reflects light, but the embodiments of this present disclosure are not limited thereto. The first electrode 151 may include a laminated structure (Ti/Al/Ti) of aluminum (Al) and titanium (Ti), a laminated structure (ITO/Al/ITO) of aluminum (Al) and ITO, or a high-reflectivity metal material such as APC alloy, and may be formed as a single layer or multiple layers, but the embodiments of this present disclosure are not limited thereto.

The organic layer 152 may be disposed on the first electrode 151. The organic layer 152 may include one or more light-emitting structures (or light-emitting devices or elements) stacked in a sequence or reverse sequence of a hole delivery layer and an electron delivery layer, arranged on the first electrode 151. For example, the hole delivery layer may include a hole transport layer, hole injecting layer, electron blocking layer, or P-type charge generating layer, but the embodiments of this present disclosure are not limited thereto. For example, the electron delivery layer may include an electron transport layer, electron injecting layer, hole blocking layer, or N-type charge generating layer, but the embodiments of this present disclosure are not limited thereto. The organic layer 152 may be an organic light-emitting layer, an inorganic light-emitting layer, a quantum dot light-emitting layer, a micro light-emitting diode, or a micro-mini light-emitting diode, but the embodiments of this present disclosure are not limited thereto. For example, the display panel 100 according to an embodiment of this present disclosure, the organic layer 152 may include an organic light-emitting layer. The organic layer 152 may include a red light-emitting layer, a green light-emitting layer, and a blue light-emitting layer. The organic layer 152 may further include a white light-emitting layer, but the embodiments of this present disclosure are not limited thereto. Hereinafter, the detailed structure of the organic layer 152 according to an embodiment will be described.

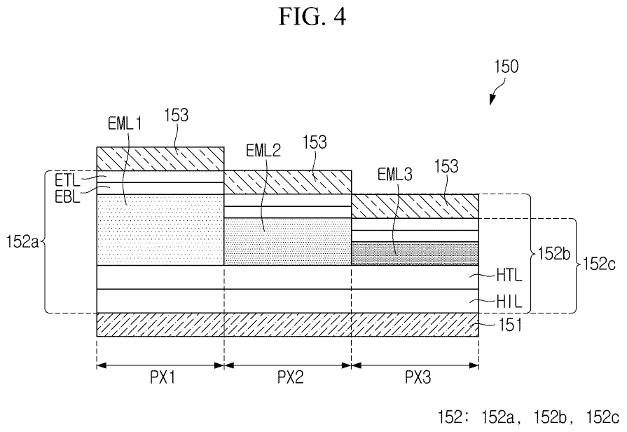

FIG. 4 is a detailed cross-sectional view of the light-emitting layer of FIG. 3.

Referring to FIG. 4, the light-emitting layer 150 may extend across a first sub-pixel PX1, a second sub-pixel PX2, and a third sub-pixel PX3.

The thickness of the light-emitting layer 150 may differ in each sub-pixel PX1, PX2, and PX3, but the embodiments of this present disclosure are not limited thereto, and the thickness of the light-emitting layer 150 in each sub-pixel PX1, PX2, and PX3 may also be the same.

The organic layer 152 may include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 in the respective organic layers 152a, 152b, and 152c may be physically separated, but the lower and upper layers of the light-emitting layers EML1, EML2, and EML3 may be integrally formed across the sub-pixels PX1, PX2, and PX3. The light-emitting layers EML1, EML2, and EML3 may differ in thickness. For example, the thickness of the first light-emitting layer EML1 may be the largest, followed by the second light-emitting layer EML2, and the thickness of the third light-emitting layer EML3 may be the smallest, but the embodiments of this present disclosure are not limited thereto.

The hole injection layer HIL may be disposed on the first electrode 151. The hole injection layer HIL may be positioned between the first electrode 151 and the light-emitting layers EML1, EML2, and EML3. The hole injection layer HIL may be integrally formed across the sub-pixels PX1, PX2, and PX3. For example, the hole injection layer HIL may be made of a hole injection material selected from the group of MTDATA, CuPc, TCTA, NPB (NPD), HATCN, TDAPB, PEDOT/PSS, F4TCNQ, and N-(biphenyl-4-yl)-9,9-dimethyl-N-(4-(9-phenyl-9H-carbazole-3-yl)phenyl)-9H-fluorene-2-amine, but the embodiments of this present disclosure are not limited thereto.

The hole transport layer HTL may be disposed on the hole injection layer HIL. The hole transport layer HTL may be positioned between the hole injection layer HIL and the light-emitting layers EML1, EML2, and EML3. The hole transport layer HTL may be integrally formed across the sub-pixels PX1, PX2, and PX3. The hole transport layer HTL may be made of one or more materials selected from a group including aryloamine-based compounds such as NPB (N,N′-naphthyl-N,N′-phenyl benzidine), TPD (N,N′-bis-(3-methylphenyl)-N,N′-bis-(phenyl)-benzidine), PPD, TTBND, FFD, p-dmDPS, TAPC, starburst aromatic amines such as TCTA, PTDATA, TDAPB, TDBA, 4-a, TCTA, spiro and ladder-type materials such as Spiro-TPD, Spiro-mTTB, Spiro-2, NPD (N,N-dinaphthyl-N,N′-diphenyl benzidine), s-TAD, and MTDATA (4,4′,4″Tris(N-3-methylphenyl-N-phenyl-amino)-triphenylamine), but the embodiments of this present disclosure are not limited thereto.

The light-emitting layers EML1, EML2, and EML3 may be disposed on the hole transport layer HTL. The first sub-pixel PX1 may have the first light-emitting layer EML1, the second sub-pixel PX2 may have the second light-emitting layer EML2, and the third sub-pixel PX3 may have the third light-emitting layer EML3.

The light-emitting layers EML1, EML2, and EML3 may differ in thickness. For example, the first light-emitting layer EML1 may have a thickness of 60 to 80 nm, the second light-emitting layer EML2 may have a thickness of 30 to 50 nm, and the third light-emitting layer EML3 may have a thickness of 10 to 30 nm, but the embodiments of this present disclosure are not limited thereto.

The first light-emitting layer EML1, the second light-emitting layer EML2, and the third light-emitting layer EML3 may include materials that emit light in the visible light spectrum by combining holes and electrons, which are transported separately.

An electron blocking layer EBL may be disposed on each of the light-emitting layers EML1, EML2, and EML3. The electron blocking layer EBL may be integrally disposed across the sub-pixels PX1, PX2, and PX3.

An electron transport layer ETL may be disposed on the electron blocking layer EBL. The electron transport layer ETL may be integrally disposed across the sub-pixels PX1, PX2, and PX3. The electron transport layer ETL may be composed of anthracene derivatives and lithium quinolate (Liq), or one or more materials selected from oxadiazole, triazole, phenanthroline, benzoxazole, benzthiazole, or benzimidazole (for example, 2-[4-(9,10-Di-2-naphthalenyl-2-anthracenyl)phenyl]-1-phenyl-1H-benzimidazole); however, the embodiments of this present disclosure are not limited thereto.

A second electrode 153 may be disposed on the electron transport layer ETL.

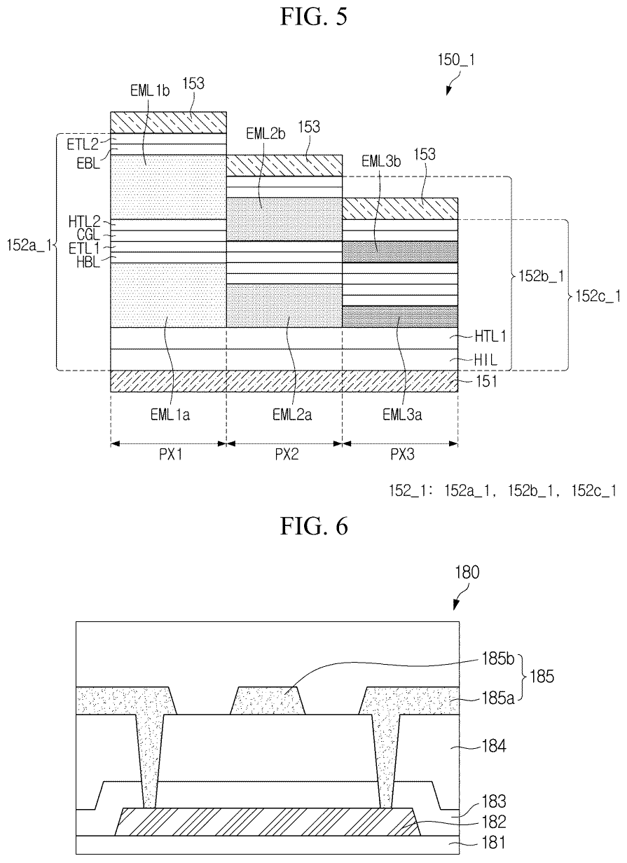

FIG. 5 is a detailed cross-sectional view of the light-emitting layer according to an alternative embodiment.

Referring to FIGS. 4 and 5, the organic layer 152_1 may include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers in respective organic layers 152a_1, 152b_1, and 152c_1 may be physically separated, but the lower and upper layers of the light-emitting layers may be integrally formed across the sub-pixels PX1, PX2, and PX3. The light-emitting layers may differ in thickness. For example, the first light-emitting layer in the first sub-pixel may have the greatest thickness, followed by the second light-emitting layer in the second sub-pixel, with the third light-emitting layer in the third sub-pixel having the smallest thickness, but the embodiments of this present disclosure are not limited thereto. Additionally, the light-emitting layers in each organic layer 152a_1, 152b_1, and 152c_1 may include two or more layers.

The hole injection layer HIL may be disposed on the first electrode 151. The hole injection layer HIL may be positioned between the first electrode 151 and the light-emitting layers EML1a, EML2a, and EML3a. The hole injection layer HIL may be integrally formed across the sub-pixels PX1, PX2, and PX3. For example, the hole injection layer HIL may be made of a hole injection material selected from the group of MTDATA, CuPc, TCTA, NPB (NPD), HATCN, TDAPB, PEDOT/PSS, F4TCNQ, and N-(biphenyl-4-yl)-9,9-dimethyl-N-(4-(9-phenyl-9H-carbazole-3-yl)phenyl)-9H-fluorene-2-amine, but the embodiments of this present disclosure are not limited thereto.

The first hole transport layer HTL1 may be disposed on the hole injection layer HIL. The first hole transport layer HTL1 may be positioned between the hole injection layer HIL and the light-emitting layers EML1a, EML2a, and EML3a. The first hole transport layer HTL1 may be integrally formed across the sub-pixels PX1, PX2, and PX3. The first hole transport layer HTL1 may be made of a material selected from a group including aryamine-based compounds such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, TAPC, starburst aromatic amines such as TCTA, PTDATA, TDAPB, TDBA, 4-a, and TCTA, spiro and ladder type materials like Spiro-TPD, Spiro-mTTB, Spiro-2, as well as NPD (N,N-dinaphthyl-N,N′-diphenyl benzidine), s-TAD, and MTDATA (4,4′,4″Tris(N-3-methylphenyl-N-phenyl-amino)-triphenylamine), but the embodiments of this present disclosure are not limited thereto.

The light-emitting layers EML1a, EML2a, and EML3a may be disposed on the first hole transport layer HTL1. The first sub-pixel PX1 may have the first light-emitting layer EML1a, the second sub-pixel PX2 may have the second light-emitting layer EML2a, and the third sub-pixel PX3 may have the third light-emitting layer EML3a. The light-emitting layers EML1a, EML2a, and EML3a may be identical to the respective light-emitting layers EML1, EML2, and EML3 in FIG. 4.

The light-emitting layers EML1a, EML2a, and EML3a may differ in thickness. For example, the first light-emitting layer EML1a may be formed with a thickness of 60 to 80 nm, the second light-emitting layer EML2a may be formed with a thickness of 30 to 50 nm, and the third light-emitting layer EML3a may be formed with a thickness of 10 to 30 nm, but the embodiments of this present disclosure are not limited thereto.

A hole blocking layer HBL may be disposed on each of the light-emitting layers EML1a, EML2a, and EML3a. The hole blocking layer HBL may be integrally disposed across the sub-pixels PX1, PX2, and PX3.

An electron transport layer ETL1 may be disposed on the hole blocking layer HBL. The first electron transport layer ETL1 may be integrally disposed across the sub-pixels PX1, PX2, and PX3. The first electron transport layer ETL1 may be composed of anthracene derivatives and lithium quinolate (Liq), or one or more materials selected from oxadiazole, triazole, phenanthroline, benzoxazole, benzthiazole, or benzimidazole (for example, 2-[4-(9,10-Di-2-naphthalenyl-2-anthracenyl)phenyl]-1-phenyl-1H-benzimidazole); however, the embodiments of this present disclosure are not limited thereto.

A common charge layer CGL may be disposed on the first electron transport layer ETL1. The common charge layer CGL may be disposed between the first electron transport layer ETL1 and the second hole transport layer HTL2. The common charge layer CGL may include a conductive material, but the embodiments of this present disclosure are not limited thereto.

The second hole transport layer HTL2 may be disposed on the common charge layer CGL. The second hole transport layer HTL2 may be positioned between the hole blocking layer HBL and the light-emitting layers EML1b, EML2b, and EML3b. The second hole transport layer HTL2 may be integrally formed across the sub-pixels PX1, PX2, and PX3. The material of the second hole transport layer HTL2 may be the same as that of the first hole transport layer HTL1, but the embodiments of this present disclosure are not limited thereto.

The light-emitting layers EML1b, EML2b, and EML3b may be disposed on the second hole transport layer HTL2. The first sub-pixel PX1 may have the first light-emitting layer EML1b, the second sub-pixel PX2 may have the second light-emitting layer EML2b, and the third sub-pixel PX3 may have the third light-emitting layer EML3b. The light-emitting layers EML1b, EML2b, and EML3b may be identical to the respective light-emitting layers EML1a, EML2a, and EML3a.

The light-emitting layers EML1b, EML2b, and EML3b may differ in thickness. For example, the first light-emitting layer EML1b may be formed with a thickness of 60 to 80 nm, the second light-emitting layer EML2b may be formed with a thickness of 30 to 50 nm, and the third light-emitting layer EML3b may be formed with a thickness of 10 to 30 nm, but the embodiments of this present disclosure are not limited thereto.

An electron blocking layer EBL may be disposed on each of the light-emitting layers EML1b, EML2b, and EML3b. The electron blocking layer EBL may be integrally disposed across the sub-pixels PX1, PX2, and PX3.

An electron transport layer ETL2 may be disposed on the electron blocking layer EBL. The second electron transport layer ETL2 may be integrally disposed across the sub-pixels PX1, PX2, and PX3. The second electron transport layer ETL2 may be made of a material selected from a group including anthracene derivatives and Lithium quinolate (Liq), oxadiazole, triazole, phenanthroline, benzoxazole, benzthiazole, or benzimidazole (for example, 2-[4-(9,10-Di-2-naphthalenyl-2-anthracenyl)phenyl]-1-phenyl-1H-benzimidazole), but the embodiments of this present disclosure are not limited thereto.

A second electrode 153 may be disposed on the second electron transport layer ETL2.

Referring back to FIG. 3, a second electrode 153 may be disposed on the organic layer 152. The second electrode 153 may be a transparent electrode that allows light to pass through, but the embodiments of this present disclosure are not limited thereto. For example, the second electrode 153 may include a transparent conductive material such as Indium Tin Oxide (ITO) or Indium Zinc Oxide (IZO), or a metal that allows visible light to pass through, but the embodiments of this present disclosure are not limited thereto.

A bank 154 may be disposed to expose the first electrode 151. The bank 154 may define the openings (or emissive areas EA1, EA2, and EA3) of the sub-pixels PX1, PX2, and PX3 and may be disposed to cover the edge (or border, or peripheral) portion of the first electrode 151. That is, the first sub-pixel PX1 may include the first emissive area EA1 and the first non-emissive area NEA1 surrounding the first emissive area EA1, the second sub-pixel PX2 may include the second emissive area EA2 and the second non-emissive area NEA2 surrounding the second emissive area EA2, and the third sub-pixel PX3 may include the third emissive area EA3 and the third non-emissive area NEA3 surrounding the third emissive area EA3. In other words, the non-emissive area NEA1, NEA2, and NEA3 may correspond to the boundaries between adjacent sub-pixels PX1, PX2, and PX3.

The bank 154 may include a first bank 154a and a second bank 154b. In this present disclosure, the first bank 154a may be a black bank, and the second bank 154b may be a transparent bank, but the embodiments of this present disclosure are not limited thereto.

The first bank 154a may include a black-colored material. For example, the first bank 154a may be composed of a material containing black pigments, or organic materials such as benzocyclobutene resin, polyimide resin, acrylic resin, or photosensitive polymers, but the embodiments of this present disclosure are not limited thereto. When made of a material containing black pigments or black dyes, the first bank 154a is may be a black bank. When made of a material containing black pigments or black dyes, the first bank 154a may block light from the outside or block light reflected from the outside, thereby improving the brightness of the display device.

The first bank 154a may include both the top surface and side surfaces. The top surface of the first bank 154a may be flat in the horizontal direction, and the side surfaces of the first bank 154a may be tapered in the thickness direction, but the embodiments of this present disclosure are not limited thereto.

The second bank 154b may be disposed on the top surface of the first bank 154a. The second bank 154b may completely cover the top surface of the first bank 154a and partially cover the side surfaces of the first bank 154a, but the embodiments of this present disclosure are not limited thereto. For example, in some embodiments, the second bank 154b may completely cover the side surfaces of the first bank 154a. In some other embodiments, the second bank 154b may not completely cover the side surfaces of the first bank 154a. In some other embodiments, the second bank 154b may partially expose the top surface of the first bank 154a. The second bank 154b may not include a black-colored material. In some embodiments, the second bank 154b may be omitted.

For example, the first bank 154a, as described above, may suppress surface reflection of external light. For example, the first bank 154a may absorb external light by including a black-colored material. In other words, the first bank 154a may include resin, a black-colored material in the resin, and additives for dispersing the black-colored material in the resin. For example, the resin may include organic materials such as benzocyclobutene resin, polyimide resin, acrylic resin, or photosensitive polymers, and the additives may include, for example, dispersants, but the embodiments of this present disclosure are not limited thereto.

The second bank 154b may have a lower content of black-colored material than the first bank 154a, or may not contain any black-colored material at all. For example, the second bank 154b may be a transparent bank, but the embodiments of this present disclosure are not limited thereto.

To distinguish the materials of the first bank 154a and the second bank 154b, an optical density is introduced.

The concept of external light absorption by the bank 154 is related to optical density. The higher the optical density (hereinafter, referred to as OD), which is an indicator of how a material absorbs light, the greater the light absorption rate may be. Conversely, the lower the optical density (OD), the higher the light transmittance may be. For example, optical density (OD) is calculated based on a reference thickness of 1 μm and may be proportional to the thickness. Hereinafter, the optical density (OD) calculated with a reference thickness of 1 μm is referred to as “reference optical density (OD).”

The second bank 154b contains fewer black-colored materials or none at all compared to the first bank 154a, so the reference optical density of the first bank 154a may be higher than the reference optical density of the second bank 154b.

On the top surface of the first bank 154a, a plurality of nanostructures NS may be arranged. The plurality of nanostructures NS may be directly arranged on the top surface of the first bank 154a. The surface height of the nanostructures NS may be higher than that of the second bank 154b, but the embodiments of this present disclosure are not limited thereto. Further details of the nanostructures NS will be provided later.

A barrier (not shown) may also be arranged on the bank 154. The barrier may be arranged at the boundaries (NEA1, NEA2, and NEA3) between the sub-pixels PX1, PX2, and PX3, but the embodiments of this present disclosure are not limited thereto. The barrier may be directly arranged on the top surface of the second bank 154b, but the embodiments of this present disclosure are not limited thereto. The barrier may serve to separate the organic layer 152 from the boundaries between adjacent sub-pixels PX1, PX2, and PX3.

In some embodiments, the first bank 154a or the second bank 154b may include a recessed trench in the downward direction. The trench may serve to separate the organic layer 152 at the boundaries of adjacent sub-pixels PX1, PX2, and PX3.

A spacer 155 may be further disposed on the second bank 154b. The spacer 155 may be made of the same material as the second bank 154b, but the embodiments of this present disclosure are not limited thereto. For example, the spacer 155 may be a transparent bank. For example, the spacer 155 may be disposed at the boundaries of at least one of the first to third sub-pixels PX1, PX2, and PX3, but the embodiments of this present disclosure are not limited thereto. The second bank 154b and spacer 155 may be formed from the same material and may be formed simultaneously through a half-tone mask, but the embodiments of this present disclosure are not limited thereto.

The organic layer 152 may be disposed on the first electrode 151, the bank 154, and the spacer 155. A second electrode 153 may be disposed on the organic layer 152.

An encapsulation layer 170 may be disposed on the second electrode 153. The encapsulation layer 170 may include one or more insulating layers. For example, the encapsulation layer 170 may include a first encapsulation layer 171, a second encapsulation layer 172 located on top of the first encapsulation layer 171, and a third encapsulation layer 173 located on top of the second encapsulation layer 172. The encapsulation layer 170 may include one or more inorganic insulating material layers and one or more organic material layers. For example, the first encapsulation layer 171 and the third encapsulation layer 173 may include inorganic insulating materials, while the second encapsulation layer 172 may include organic materials, but the embodiments of this present disclosure are not limited thereto.

A touch layer 180 may be disposed on the encapsulation layer 170. The touch layer 180 may include a touch buffer layer 181, a first touch conductive layer, a first touch insulating layer 183, a second touch insulating layer 184, and a second touch conductive layer. In some embodiments, one or more touch organic layers may be further disposed on the second touch conductive layer, but the embodiments of this present disclosure are not limited thereto.

FIG. 6 is a cross-sectional view of the touch layer according to FIG. 3.

Referring to FIGS. 3 and 6, a touch buffer layer 181 may be disposed on the encapsulation layer 170. For example, the touch buffer layer 181 may be disposed on the third encapsulation layer 173. The touch buffer layer 181 may be made of the same material as the buffer layer 102, but the embodiments of this present disclosure are not limited thereto.

A first touch conductive layer may be disposed on the touch buffer layer 181. The first touch conductive layer may include a bridge electrode 182. The bridge electrode 182 and the sensor electrode 185, which will be described later, may be disposed at the boundaries between adjacent sub-pixels PX1, PX2, and PX3. For example, the bridge electrode 182 and the sensor electrode 185 may be disposed in the non-emissive areas NEA1, NEA2, and NEA3. The bridge electrode 182 and the sensor electrode 185 may overlap with the black matrix BM, which will be described later, in the thickness direction. The black matrix BM may cover the bridge electrode 182 and the sensor electrode 185. As a result, the visibility of the bridge electrode 182 and the sensor electrode 185 from the outside may be prevented.

The first touch insulating layer 183 and the second touch insulating layer 184 on top of the first touch insulating layer 183 may be disposed on the first touch conductive layer. The first touch insulating layer 183 and the second touch insulating layer 184 on top of the first touch insulating layer 183 may prevent a short circuit between the first touch conductive layer and the second touch conductive layer. The first touch insulating layer 183 may be formed of silicon oxide (SiOx), silicon nitride (SiNx), or a multilayer thereof, but the embodiments of this present disclosure are not limited thereto. The second touch insulating layer 184 may include an organic insulating material; however, the embodiments of this present disclosure are not limited thereto and may also include the same material as the first touch insulating layer 183.

A second touch conductive layer may be disposed on the second touch insulating layer 184. The second touch conductive layer may include a first sensor electrode 185a and a second sensor electrode 185b. The sensor electrodes 185 may include the first sensor electrode 185a extending in a first direction DR1 (see FIG. 1) and the second sensor electrode 185b extending in a second direction DR2 (see FIG. 1) different from the first direction DR1.

The bridge electrode 182 may be electrically connected to the first sensor electrode 185a through a contact hole formed in the first touch insulating layer 183 and the second touch insulating layer 184. For example, the first sensor electrode 185a and the bridge electrode 182 may extend in the first direction DR1 (see FIG. 1).

The sensor electrodes 185 and the bridge electrode 182 may include a metallic material. For example, they may be formed of titanium (Ti), nickel (Ni), aluminum (Al), or an alloy thereof and may be composed of three layers, such as titanium (Ti)/aluminum (Al)/titanium (Ti), but the embodiments of this present disclosure are not limited thereto.

Referring back to FIG. 3, a filter insulating layer 114 may be disposed on the second touch conductive layer. The filter insulating layer 114 may be formed of an inorganic insulating material such as silicon nitride (SiNx) or silicon oxide (SiOx), but the embodiments of this present disclosure are not limited thereto.

A black matrix BM may be disposed on the filter insulating layer 114. The black matrix BM may include a black-based material. For example, the black matrix (BM) may include a light-blocking material or a light-absorbing material. For example, the black matrix (BM) may be composed of a material containing black pigments or black dyes. The black matrix BM may cover the bridge electrode 182 and the sensor electrode 185. As a result, the bridge electrode 182 and the sensor electrode 185 may be prevented from being visible from the outside. For example, the width of the black matrix BM may be smaller than that of the bank 154.

For example, the separation distance between the edge of the black matrix BM and the boundary between the emissive areas (EA1, EA2, and EA3) and the non-emissive areas (NEA1, NEA2, and NEA3) may be greater than the separation distance between the edge of the bank 154 (or the first bank 154a) and the boundary between the emissive areas (EA1, EA2, and EA3) and the non-emissive areas (NEA1, NEA2, and NEA3). The edge of the bank 154 may be aligned with the boundary between the emissive areas (EA1, EA2, and EA3) and the non-emissive areas (NEA1, NEA2, and NEA3), but the embodiments of this present disclosure are not limited thereto. In the display panel 100 according to an embodiment, since the first bank 154a may include a black-colored material and the separation distance between the edge of the black matrix BM and the boundary between the emissive areas (EA1, EA2, and EA3) and the non-emissive areas (NEA1, NEA2, and NEA3) is greater than the separation distance between the edge of the first bank 154a and the same boundary, light emitted from the emissive areas (EA1, EA2, and EA3) may have a wider viewing angle and be emitted upward through the space created by this separation. As a result, the reduction in brightness due to the viewing angle can be improved. However, when the separation distance between the edge of the black matrix BM and the boundary between the emissive areas (EA1, EA2, and EA3) and non-emissive areas (NEA1, NEA2, and NEA3) is greater than the separation distance between the edge of the first bank 154a and the boundary between the emissive areas (EA1, EA2, and EA3) and non-emissive areas (NEA1, NEA2, and NEA3), and when the bank 154 is made of only transparent material, external light incident on the bank 154 may be reflected by the bank 154, causing visible halo patterns. In a display panel 100 according to an embodiment, external light incident on the first bank 154a, which contains a black material, is absorbed or blocked, thereby improving the occurrence of halo patterns.

The color filters 191, 192, and 193 may be disposed on the black matrix BM. The color filters 191, 192, and 193 may be arranged in the first to third sub-pixels PX1, PX2, and PX3, respectively, to block specific colors from the light emitted from the emissive areas EA1, EA2, and EA3 of the respective sub-pixel PX1, PX2, and PX3. The first color filter 191 may be configured to block all colors except for red (R) light. In this case, the first color filter 191 may be a red color filter. The second color filter 192 may be configured to block all colors except for green (G) light. In this case, the second color filter 192 may be a green color filter. The third color filter 193 provided in the third sub-pixel PX3 may be configured to block all colors except for blue (B) light. In this case, the third color filter 193 may be a blue color filter. However, the embodiments of this present disclosure are not limited thereto.

For example, the color filters 191, 192, and 193 may directly contact the sides and upper surfaces of the black matrix BM, respectively. For example, each color filter 191, 192, and 193 may be spaced from the boundary of adjacent sub-pixels PX1, PX2, and PX3, but the embodiments of this present disclosure are not limited to this, and the filters may overlap in the thickness direction.

A planarization layer OC may be disposed on the color filters 191, 192, and 193. The planarization layer OC may serve to flatten the step formed by the color filters 191, 192, and 193. For example, the planarization layer OC may include an organic insulating material.

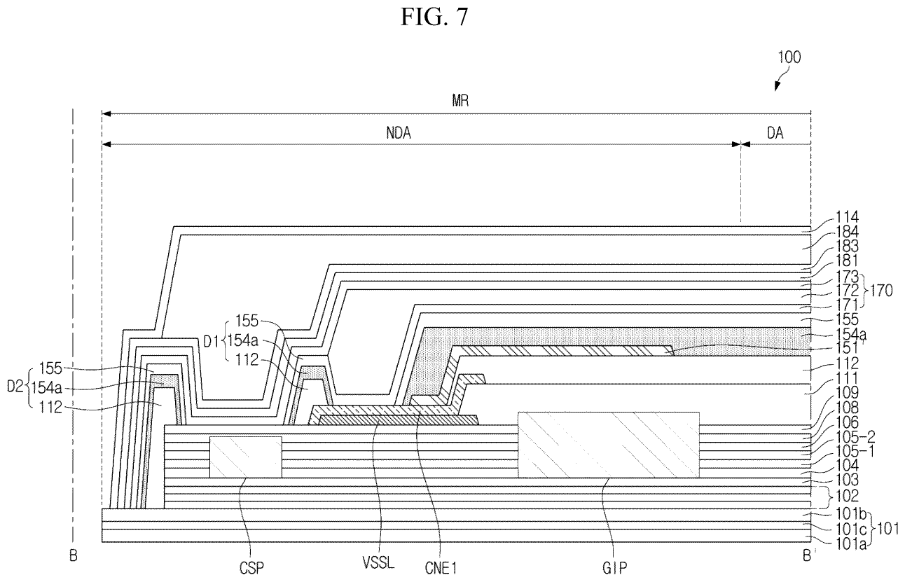

FIG. 7 is a cross-sectional view taken along line B-B′ of FIG. 1.

Referring to FIG. 7, at least one of the panel inorganic layers 102, 103, 104, 105-1, 105-2, 106, 108, and 109 may not extend to the edge of the substrate 101. That is, at least one of the panel inorganic layers 102, 103, 104, 105-1, 105-2, 106, 108, and 109 may expose the edge of the substrate 101, but the embodiments of this present disclosure are not limited thereto.

In an embodiment, the display panel 100 may further include a crack detection pattern CSP, a low-potential voltage line VSSL, and a gate driving unit GIP. As described in FIG. 1, the low-potential voltage line VSSL may be located between the crack detection pattern CSP and the display area DA, and the gate driving unit GIP may be located between the low-potential voltage line VSSL and the display area DA.

For example, the gate driving unit GIP may include a conductive layer positioned in the same layer as the first gate electrode 122 (see FIG. 3), a conductive layer positioned in the same layer as the second light-blocking layer 136 (see FIG. 3), or a conductive layer positioned in the same layer as the first source electrode 121, but the embodiments of this present disclosure are not limited thereto.

For example, the crack detection pattern CSP may be arranged between the first dam D1 and the second dam D2. The crack detection pattern CSP may be composed of a conductive layer positioned in the same layer as the first gate electrode 122 (see FIG. 3) or a conductive layer positioned in the same layer as the second light-blocking layer 136 (see FIG. 3), but the embodiments of this present disclosure are not limited thereto. For example, the crack detection pattern CSP may include a conductive layer positioned in the same layer as the first source electrode 121, but the embodiments of this present disclosure are not limited thereto.

The low-potential voltage line VSSL may be arranged between the crack detection pattern CSP and the gate driving unit GIP. The low-potential voltage line VSSL may be composed of a conductive layer positioned in the same layer as the first source electrode 121, but the embodiments of this present disclosure are not limited thereto.

The first protective layer 111 may cover the gate driving unit GIP, partially cover one end of the low-potential voltage line VSSL, and expose another portion of the low-potential voltage line VSSL. In this present disclosure, one end refers to the area located in the direction towards the display area DA from a non-display area NDA, and the other end refers to the area located in the direction towards the non-display area NDA from a display area DA.

The first protective layer 111 may have the first connection electrode CNE1 arranged in the same layer as the connection electrode 145. The first connection electrode CNE1 may be directly connected to the area of the low-potential voltage line VSSL exposed by the first protective layer 111. The first connection electrode CNE1 may cover the other end of the low-potential voltage line VSSL, but the embodiments of this present disclosure are not limited thereto.

The second protective layer 112 may be arranged on the first connection electrode CNE1. The second protective layer 112 may directly contact and cover one end of the first connection electrode CNE1, while exposing another portion of the first connection electrode CNE1. The second protective layer 112 may constitute the first layer of the first dam D1 and the first layer of the second dam D2. The second dam D2 may overlap with, for example, the low-potential voltage line VSSL and cover the other end of the low-potential voltage line VSSL. The second dam D2 may directly contact the first connection electrode CNE1 and cover the other end of the first connection electrode CNE2. The second protective layer 112, which forms the first layer of the first dam D1, may directly contact the exposed side surfaces of at least one of the panel inorganic layers 102, 103, 104, 105, 106, 107, and 109, and may directly contact the upper surface of the substrate 101, but the embodiments of this present disclosure are not limited thereto. The second protective layer 112 may overlap with the gate driving unit GIP. Although the dam is illustrated as consisting of two parts in this present disclosure, the dam may be composed of three or more parts, or even just one part.

A low-potential connection electrode 151′ positioned in the same layer as the first electrode 151 (see FIG. 3) may be placed on the first connection electrode CNE1 exposed by the second protective layer 112 and on top of the second protective layer 112. The low-potential connection electrode 151′ may be electrically connected to the first connection electrode CNE1 exposed by the second protective layer 112. The low-potential connection electrode 151′ may be electrically connected to the second electrode 153 (see FIG. 3) as described with reference to FIG. 3.

A bank 154 may be disposed on top of the low-potential connection electrode 151′ and the second protective layer 112. The bank 154 may overlap with the gate driving unit GIP and the low-potential connection electrode 151′, covering the other end of the low-potential connection electrode 151′. The bank 154 may fully cover the low-potential connection electrode 151′, but the embodiments of this present disclosure are not limited thereto. The bank 154 may expose the center and the other end of the first connection electrode CNE1, but the embodiments of this present disclosure are not limited thereto. The first bank 154a may form the second layer of the first dam D1 and the second layer of the second dam D2. In each of the dam D1 and D2, the first bank 154a may overlap with the second protective layer 112 forming the first layer and may completely cover the second protective layer 112, but the embodiments of this present disclosure are not limited thereto. In the second dam D2, the first bank 154a may contact the side of the second protective layer 112 and the upper surface of the substrate 101, but the embodiments of this present disclosure are not limited thereto.

A spacer 155 may be disposed on the first bank 154a. The spacer 155 may overlap with the gate driving unit GIP. The spacer 155 may form the third layer of the dams D1 and D2. The spacer 155 forming the third layer of each of the dams D1 and D2 may overlap with the bank 154 forming the second layer and may completely cover the first bank 154a, but the embodiments of this present disclosure are not limited thereto. In the second dam D2, the spacer 155 may contact the side of the first bank 154a and the upper surface of the substrate 101, but the embodiments of this present disclosure are not limited thereto.

An encapsulation layer 170 may be disposed on the spacer 155. The first encapsulation layer 171 extends to the gate driving unit GIP, the low-potential voltage line VSSL, the first dam D1, and the second dam D2, and may cover the outer surface of the second dam D2. The second encapsulation layer 172 may terminate at the first dam D1. The second encapsulation layer 172 may overlap with the gate driving unit GIP and the low-potential voltage line VSSL. The third encapsulation layer 173 extends to the gate driving unit GIP, the low-potential voltage line VSSL, the first dam D1, and the second dam D2, and may directly contact the first encapsulation layer 171 on the first dam D1, the crack detection pattern CSP, and the second dam D2.

The touch buffer layer 181 and the first touch insulating layer 183 extend to the gate driving unit GIP, the low-potential voltage line VSSL, the first dam D1, and the second dam D2, and may cover the outer surface of the second dam D2. The second touch insulating layer 184 extends to the gate driving unit GIP, the low-potential voltage line VSSL, the first dam D1, and the crack detection pattern CSP, and may terminate on the second dam D2, but the embodiments of this present disclosure are not limited thereto.

The filter insulating layer 184 extends to the gate driving unit GIP, the low-potential voltage line VSSL, the first dam D1, and the second dam D2, and may directly contact the outer surface of the second touch insulating layer 184, but the embodiments of this present disclosure are not limited thereto.

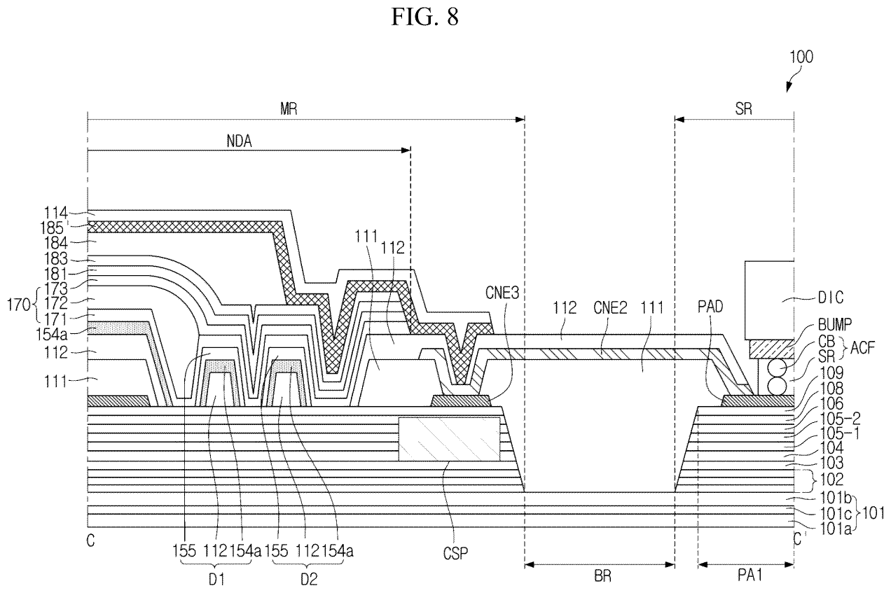

FIG. 8 is a cross-sectional view taken along line C-C′ of FIG. 1.

Referring to FIG. 3, FIG. 7, and FIG. 8, a bending region BR may be disposed between the sub-region SR and the crack detection pattern CSP. In the bending region BR, the panel inorganic layers 102, 103, 104, 105, 106, 107, and 109 may be removed, exposing the upper surface of the substrate 101.

In the first pad area PA1, a pad electrode PAD disposed in the same layer as the first source electrode 121 (see FIG. 3) is arranged, and a third connection electrode CNE3 disposed in the same layer as the first source electrode 121 (see FIG. 3) may be arranged on the crack detection pattern CSP.

A first protective layer 111 may be disposed on the pad electrode PAD and the third connection electrode CNE3. The first protective layer 111 is arranged in the bending region BR to directly contact the upper surface of the substrate 101 and the side surfaces of the panel inorganic layers 102, 103, 104, 105, 106, 107, and 109.

The second connection electrode CNE2 is arranged on the first protective layer 111, which may be positioned in the same layer as the connection electrode 145 (see FIG. 3). The second connection electrode CNE2 may electrically connect the pad electrode PAD and the third connection electrode CNE3. The second connection electrode CNE2 may be arranged across the bending region BR and the first pad area PA1 and above the crack detection pattern CSP.

The data driving unit DIC may be arranged on the pad electrode PAD. The data driving unit DIC includes bumps BUMP, and an anisotropic conductive film ACF is disposed between the pad electrode PAD and the bumps BUMP, electrically connecting the pad electrode PAD and the bumps BUMP. The anisotropic conductive film ACF may contain a plurality of conductive balls CB dispersed in a resin RS. Through the conductive balls CB, the pad electrode PAD, and the bumps BUMP may be electrically connected.

A second protective layer 112 may be disposed on the second connection electrode CNE2. The second protective layer 112 may expose the pad electrode PAD.

The first and second encapsulation layers 171 and 173 of the encapsulation layer 170 may extend up to the bending region BR. For example, the first and second encapsulation layers 171 and 173 may extend up to the crack detection pattern CSP and may also overlap with the crack detection pattern CSP, but the embodiments of this present disclosure are not limited thereto. The first and second encapsulation layers 171 and 173 may not be disposed in the bending region BR.

The touch buffer layer 181 and the first touch insulating layer 183 may extend up to the bending region BR. For example, the touch buffer layer 181 and the first touch insulating layer 183 may extend up to the crack detection pattern CSP and may also overlap with the crack detection pattern CSP, but the embodiments of this present disclosure are not limited thereto. The touch buffer layer 181 and the first touch insulating layer 183 may not be disposed in the bending region BR.

The second touch insulating layer 184 may overlap with the first dam D1 and the second dam D2. The second touch insulating layer 184 may not be disposed on the outer side of the second dam D2, but the embodiments of this present disclosure are not limited thereto.

The touch connection wiring 185′ may be electrically connected to the second connection electrode CNE2. The touch connection wiring 185′ may serve to provide the signal applied from the pad electrode PAD and the second connection electrode CNE2 to the first sensor electrode 185a or the second sensor electrode 185b, as described with reference to FIG. 3. The touch connection wiring 185′ may be located in the same layer as the second touch conductive layer (first sensor electrode 185a in FIG. 3) or may also be located in the same layer as the first touch conductive layer (bridge electrode 182 in FIG. 3) or consist of two layers of the first and second touch conductive layers, but the embodiments of this present disclosure are not limited thereto.

The touch connection wiring 185′ may have a filter insulating layer 114 disposed thereon, and the filter insulating layer 114 may not be disposed in the bending region BR.

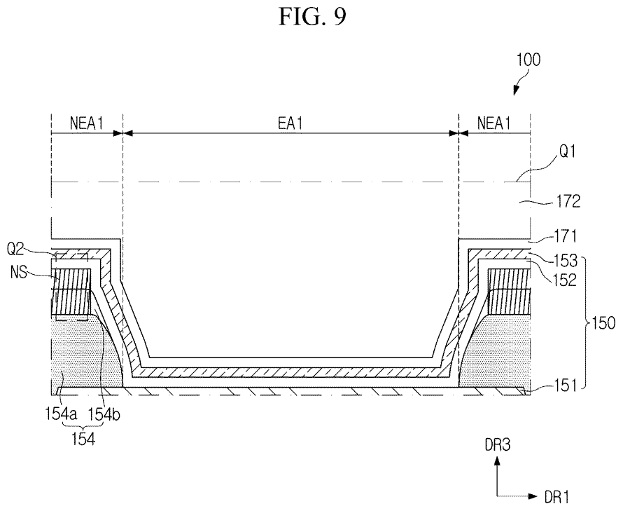

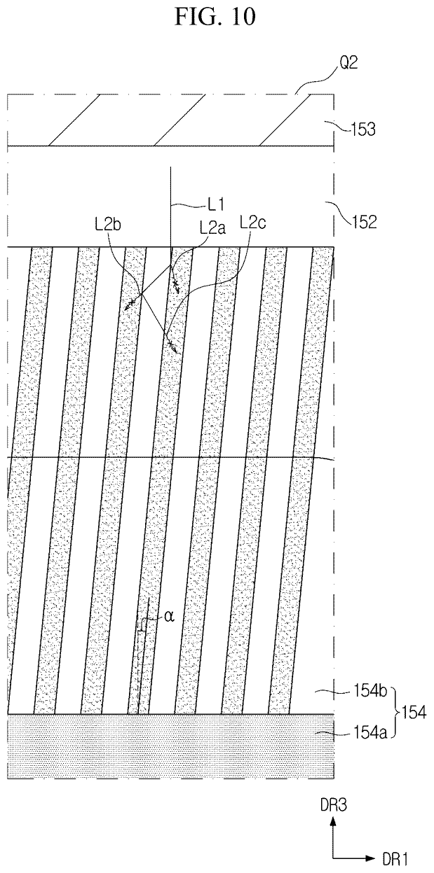

FIG. 9 is an enlarged cross-sectional view of the Q1 area of FIG. 3. FIG. 10 is an enlarged cross-sectional view of the Q2 area of FIG. 9. FIG. 9 is shown centered around the first sub-pixel PX1.

Referring to FIG. 9 and FIG. 10, the nanostructure NS may be directly arranged on the upper surface of the first bank 154a and extend in the upward direction. The surface height of the nanostructure NS may be higher than the surface height of the second bank 154b, but the embodiments of this present disclosure are not limited thereto. An organic layer 152 may be disposed on the surface of the nanostructure NS. The organic layer 152 may be arranged along the surfaces of the plurality of nanostructures NS. For example, the organic layer 152 may be arranged along the top surface and the side surfaces formed by the plurality of nanostructures NS, but the embodiments of this present disclosure are not limited thereto.

The front tilt angle (α) of the nanostructure NS may be 30 degrees or less. In this present disclosure, the front tilt angle (α) refers to the tilted angle relative to the third direction DR3.

Although the nanostructures NS are depicted with the same front tilt angle (α) and the same length (in the upward direction) in FIG. 10, this is not limiting, and the nanostructures NS may vary in the front tilt angle (α), provided it is equal to or less than about 30 degrees, and in length.

The nanostructures NS may include inorganic materials or organic materials. For example, the nanostructures NS may include metal oxides. For example, the metal oxide may include ZnO, but the embodiments of this present disclosure are not limited thereto.

For example, the nanostructures NS may include nanowires, nanotubes, or micro-porous structures, but the embodiments of this present disclosure are not limited thereto.

As shown in FIG. 10, the first light L1 (or external light) passes through the organic layer 152. The first light L1 that passes through the organic layer 152 may be absorbed as denoted by L2a, reflected, or scattered by specific nanostructures NS. As described above, since the front tilt angle α of the nanostructures NS is about 30 degrees or less, light that is reflected or scattered by specific nanostructures NS travel in the downward direction. Light that is reflected or scattered and travels downward by specific nanostructures NS may be absorbed, as denoted by L2b, by adjacent nanostructures NS, or reflected or scattered and absorbed, as denoted by L2c, by specific nanostructures NS.

In this way, the first light L1 incident on the plurality of nanostructures NS may be absorbed, reflected, or scattered within the plurality of nanostructures NS and eventually be absorbed or dissipated.

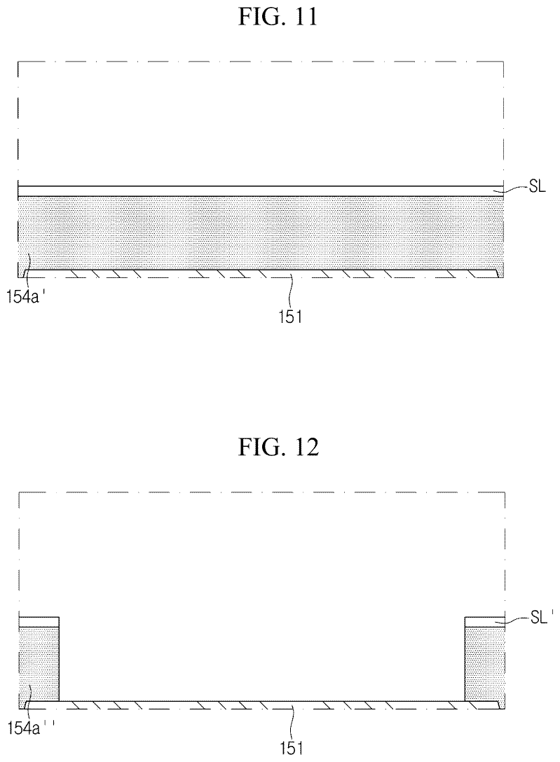

FIGS. 11 to 14 are cross-sectional views illustrating the process steps of a manufacturing method for a display panel according to an embodiment;

As shown in FIG. 11, a first bank layer 154a′ is formed over the first electrode 151, spanning the first emissive area EA1 and the first non-emissive area NEA1. A seed layer SL is formed over the first bank layer 154a′. The seed layer SL may be a solution containing a precursor for forming the nanostructures NS described with reference to FIG. 9. For example, the seed layer SL may be a solution containing a zinc precursor (e.g., Zn ions), but the embodiments of this present disclosure are not limited thereto.

As shown in FIG. 12, the first bank layer 154a′ and the seed layer SL from FIG. 11 are patterned to form the first bank layer 154a′ and the seed layer SL′ arranged in the first non-emissive area NEA1. The patterning of the first bank layer 154a′ and the seed layer SL in FIG. 12 may include exposure of the first bank layer 154a′ and the seed layer (SL) in the first non-emissive area NEA1 in FIG. 11 and developing the first bank layer 154a′ and the seed layer SL in the first emissive area EA1 in FIG. 11.

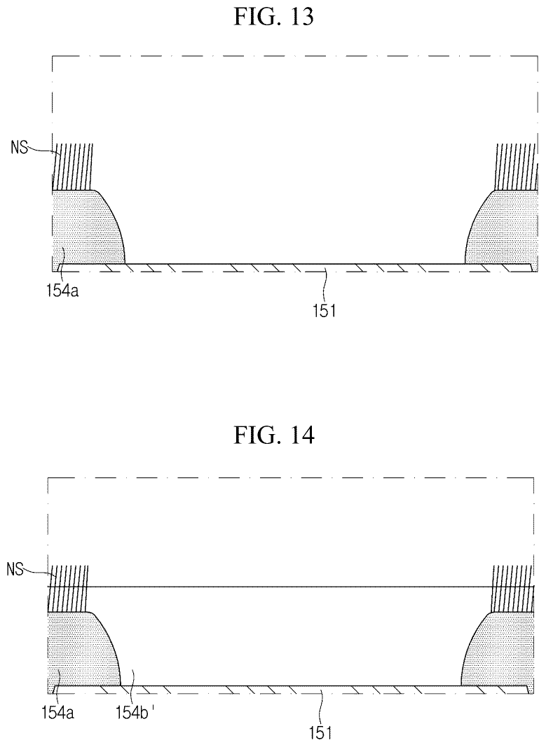

Next, as shown in FIG. 13, heat treatment (baking) is performed to form the first bank 154a, and a plurality of nanostructures NS may be formed from the seed layer SL′ in FIG. 12.

Then, as shown in FIG. 14, the second bank layer 154b′ is formed. Subsequently, through patterning of the second bank layer 154b′, the second bank 154b in FIG. 9 is formed.

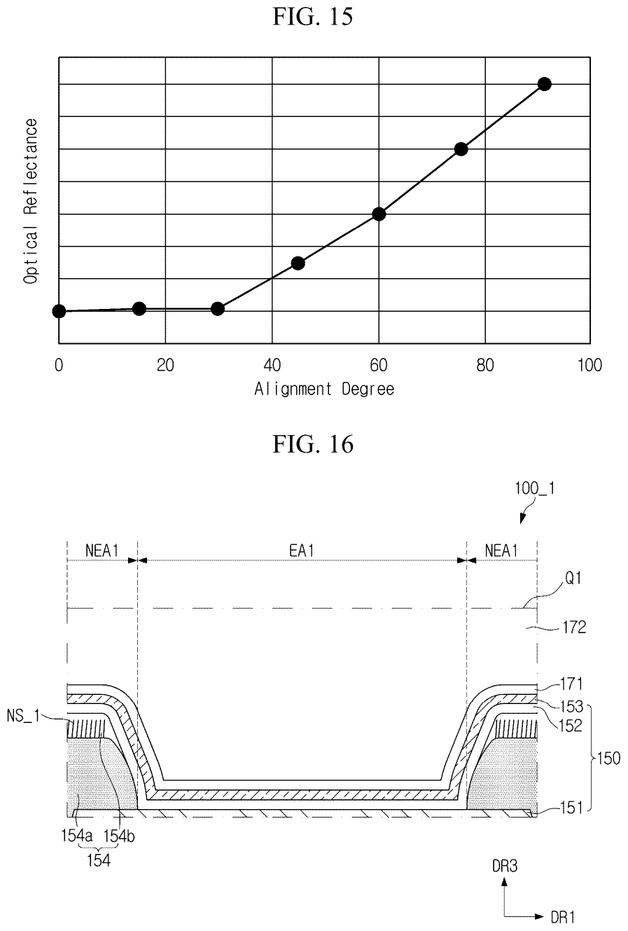

FIG. 15 is a graph illustrating light reflectivity according to the inclination of nanostructures according to an embodiment. In FIG. 15, the horizontal axis of the graph represents the front tilt angle (alignment degree) of the nanostructures NS, and the vertical axis represents the optical reflectance caused by the nanostructures NS.

As shown in FIG. 15, the light reflectance does not increase when the front slope (α) of the nanostructure NS is between 0 degrees and approximately 30 degrees or less, but increases linearly when the front slope (α) exceeds approximately 30 degrees. Therefore, to absorb external light through the nanostructure NS, it is preferable for the front slope (α) of the nanostructure (NS) to be approximately 30 degrees or less.

Hereinafter, descriptions are provided of the display devices according to other embodiments. In the following embodiments, detailed explanations of the reference numerals or configurations already described with reference to FIGS. 1 to 15 will be omitted to avoid redundancy.

FIG. 16 is a cross-sectional view of a display device according to another embodiment.

The display panel 100_1 of the display device according to the embodiment of FIG. 16 differs from the display panel 100 according to the embodiment of FIG. 9 in that the surface height of the nanostructures NS_1 may be lower than the surface height of the second bank 154b.

Other explanations are omitted as they have been detailed above with reference to FIG. 9.

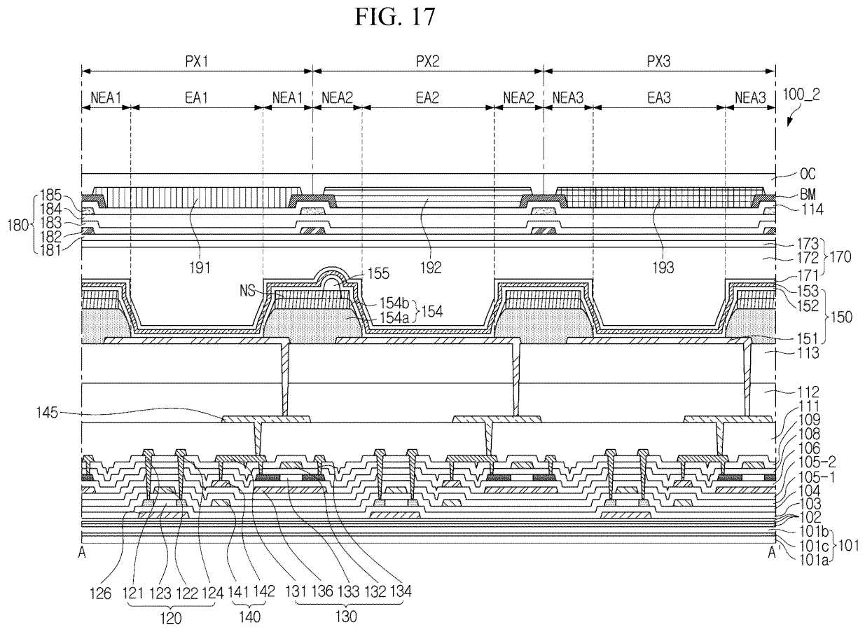

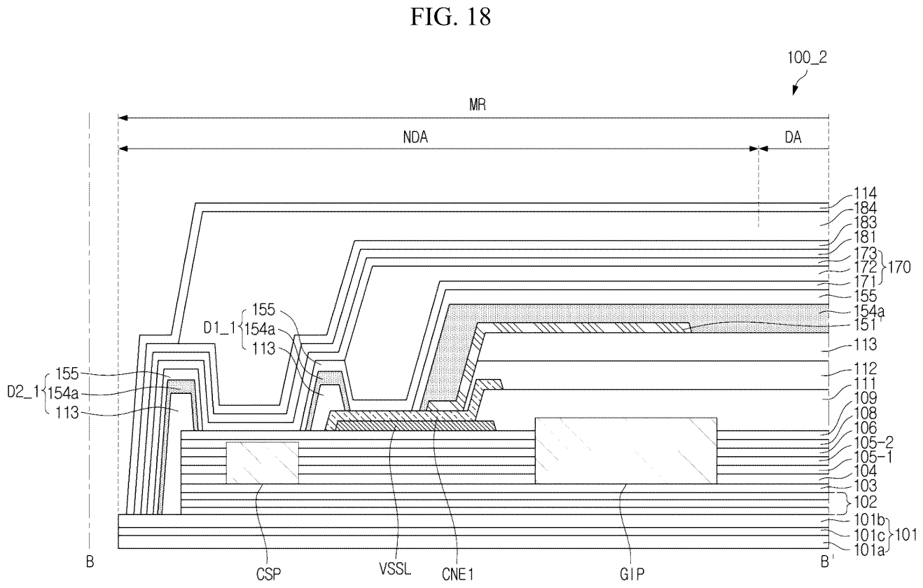

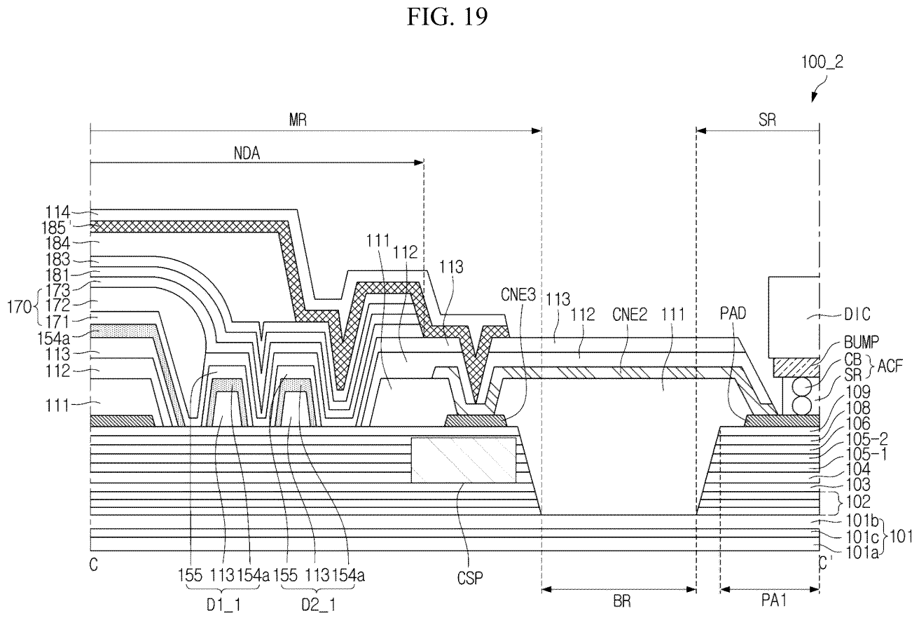

FIG. 17 is a cross-sectional view of a display device according to another embodiment. FIG. 18 is a cross-sectional view of a display device according to another embodiment. FIG. 19 is a cross-sectional view of a display device according to another embodiment;

The display panel 100_2 of the display device according to the embodiment of FIGS. 17 to 19 differs from the display panel 100 according to the embodiment of FIGS. 3, 7, and 8 in that a third protective layer 113 is further included on the second protective layer 112.

In more detail, the display panel 100_2 according to this may further include a third protective layer 113 between the second protective layer 112 and the first electrode 151. The material of the third protective layer 113 may include at least one of the materials exemplified for the second protective layer 112, but the embodiments of this present disclosure are not limited thereto.

As shown in FIGS. 18 and 19, the first dam D1_1 and the second dam D2_1 each include the third protective layer 113 as a first layer and may not include the second protective layer 112; however, the embodiments of this present disclosure are not limited thereto.

Other explanations are omitted as they have been detailed above with reference to FIGS. 3, 7, and 8.

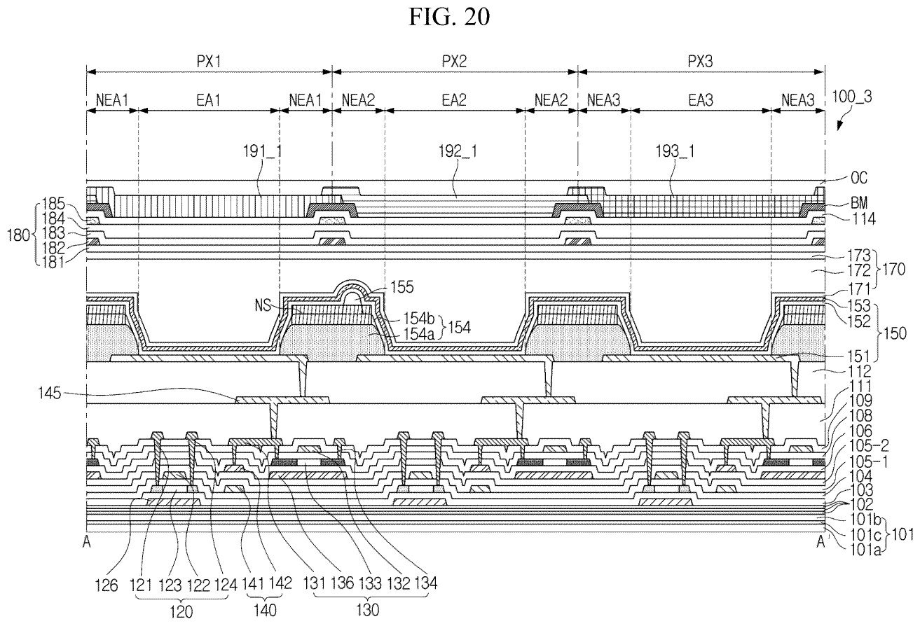

FIG. 20 is a cross-sectional view of a display device according to another embodiment.

The display panel 100_3 of the display device according to the embodiment of FIG. 20 differs from the display panel 100 according to the embodiment of FIG. 3 in that the color filters 191_1, 192_1, and 193_1 may overlap in the non-emissive areas NEA1, NEA2, and NEA3.

Although FIG. 20 illustrates that the second color filter 192_1 is positioned at the top in each of the non-emissive areas NEA1, NEA2, and NEA3, followed by the first color filter 191_1 and the third color filter 193_1 at the bottom, the stacking order of the color filters 191_1, 192_1, and 193_1 in the non-emissive areas NEA1, NEA2, and NEA3 may vary depending on the manufacturing process sequence.

Other explanations are omitted as they have been detailed above with reference to FIG. 3.

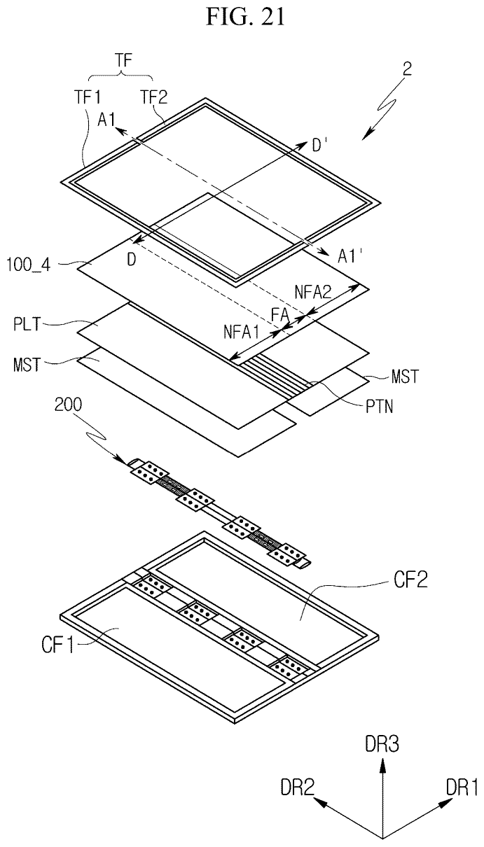

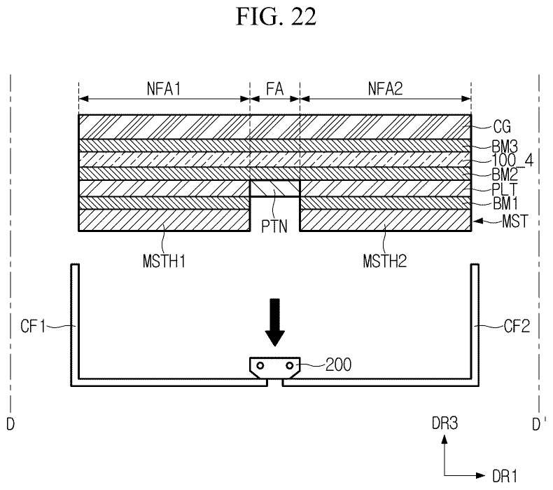

FIG. 21 is a perspective view of a display device according to another embodiment; and FIG. 22 is a cross-sectional view taken along line D-D′ of FIG. 21.

The display device 2 according to the embodiment of FIGS. 21 and 22 differs from the display device 1 according to the embodiment of FIG. 1 in that it is a foldable display device.

In this present disclosure, the folding axis A1 around which the display device 2 folds may be the same as the second direction DR2.

A top frame TF is arranged at the topmost part of the display device 2. The top frame TF includes a first top frame TF1 arranged on one side and a second top frame TF2 arranged on the opposite side, with respect to the folding axis A1. The top frame TF is positioned to cover the edges of the display panel 100_3. The top frame TF may protect the display panel 100_4 from external impacts. The top frame TF may form the bezel of the display device 2.

A cover layer CG may be placed beneath the top frame TF. The cover layer CG is arranged on top of the display panel 100_4.

By being placed on top of the display panel 100_4, the cover layer CG serves to protect the components placed underneath from external forces.

The panel assembly is arranged on the underside of the cover layer CG. The panel assembly includes the display panel 100_4 and a plate PLT. The display panel 100_4 may be substantially the same as any of the display panels 100, 100_1, 100_2, or 100_3 described earlier.

The plate PLT may be placed beneath the display panel 100_4 and include various plates that support the display panel 100_4. For example, one or more plates may include a back plate that supports the display panel 100_4, a top plate formed of SUS material placed beneath the back plate, a bottom plate formed of SUS material with patterns formed at the folding section placed beneath the top plate, a heat dissipation sheet for heat dissipation, and a middle plate covering the non-planar surface due to the various components of the hinge assembly.

The plate PLT may have a slit pattern PTN formed thereon. The slit pattern PTN may be formed at the position corresponding to the folding area FA of the display panel 100_4. The slit pattern PTN may be an etched section in the shape of a slit formed in the plate PLT. The plate PLT may be made of metal, such as SUS material, which may cause the plate PLT to encounter resistance when folding or unfolding due to the metal's strength. The slit pattern PTN may provide flexibility to the plate PLT.

A middle plate MST is placed beneath the panel assembly. The middle plate MST supports the components arranged thereabove. Additionally, beneath the middle plate MST, the hinge assembly 200 and the cover frame CF are placed, upper surfaces of which may be uneven. The middle plate MST may flatten the non-planar lower surface. The middle plate MST may be made of materials such as plastic, polyimide, or metal to enhance the rigidity of the display device 2. For example, the middle plate MST may include aluminum or SUS, but the embodiments of this present disclosure are not limited to these materials.

The middle plate MST may include a first middle plate portion MSTH1 positioned in the first unfolding area NFA1 and a second middle plate portion MSTH2 positioned in the second unfolding area NFA2.

Below the panel assembly, the hinge assembly 200 is placed. The hinge assembly 200 is positioned at the lower part of the folding area FA. The hinge assembly 200 may have an elongated shape along the folding axis A1. The hinge assembly 200 may perform a folding motion with rotation on one side and the other side relative to the folding axis A1.

Beneath the hinge assembly 200, the cover frame CF is placed. A receiving groove may be formed on the upper surface of the cover frame CF, where a portion of the hinge assembly 200 may rest. The cover frame CF includes a first cover frame CF1 arranged on one side of the folding axis A1 and a second cover frame CF2 arranged on the opposite side. The cover frame CF may serve as a housing that defines the sides and rear of the display device 2. The cover frame CF can protect the display device 2 from external impacts. The cover frame CF can be coupled with the hinge assembly 200. Depending on the rotation of the cover frames CF1 and CF2, the folding and unfolding of the display device 2 may be implemented.

Additional coupling members BM1, BM2, and BM3 may be arranged between adjacent components MST, PLT, PNL, and CG to join the components together. The first coupling member BM1 may couple the middle plate portions MSTH1 and MSTH2 with the upper plate PLT in the respective unfolding areas NFA1 and NFA2, the second coupling member BM2 may couple the plate (PLT and PTN) with the upper display panel 100_4, and the third coupling member BM3 may couple the display panel 100_4 with the cover layer CG.

The coupled plate PLT and middle plate MST may be seated on the cover frames CF1 and CF2. The display device 2 may perform folding and unfolding actions through the hinge assembly 200 placed on the cover frames CF1 and CF2.

Detailed explanations regarding the display panel 100_4, as have already been made, will be omitted.

The display device according to various embodiments of this present disclosure may be described as follows.

A display device according to various embodiments of this present disclosure includes a substrate, a display area including a plurality of sub-pixels, a non-display area outside the display area, a first electrode arranged on the substrate for each of the sub-pixels, a first bank arranged on the first electrode, located at a boundary between adjacent sub-pixels, and overlapping a peripheral region of an upper surface of the first electrode, and a plurality of nanostructures disposed on an upper surface of the first bank.

In the display device according to various embodiments of this present disclosure, the first bank may include a black-colored material.

The display device according to various embodiments of this present disclosure may further include a second bank on the first bank, wherein the first bank may have an optical density greater than an optical density of the second bank.

In the display device according to various embodiments of this present disclosure, the first bank may include a black bank, and the second bank may include a transparent bank.

In the display device according to various embodiments of this present disclosure, the plurality of nanostructures may have a surface height greater than a surface height of the second bank.

In the display device according to various embodiments of this present disclosure, the plurality of nanostructures may have a surface height lower than a surface height of the second bank.

In the display device according to various embodiments of this present disclosure, the plurality of nanostructures may have a tilt angle equal to or less than 30 degrees with respect to a front of the display device.

In the display device according to various embodiments of this present disclosure, the plurality of nanostructures may include nanowires, nanotubes, or a micro-porous structure.

In a display device according to various embodiments of this present disclosure, the plurality of nanostructures may include a metal oxide or an organic material.

In the display device according to various embodiments of this present disclosure, the plurality of nanostructures may be directly arranged on the upper surface of the first bank.

The display device according to various embodiments of this present disclosure may further include an organic layer disposed on the first electrode, wherein the plurality of sub-pixels may include a first sub-pixel, a second sub-pixel, and a third sub-pixel, and the organic layer may be arranged across the first sub-pixel to the third sub-pixel.

In the display device according to various embodiments of this present disclosure, the organic layer may constitute a first light-emitting layer in the first sub-pixel, a second light-emitting layer in the second sub-pixel, and a third light-emitting layer in the third sub-pixel.

In the display device according to various embodiments of this present disclosure, the first light-emitting layer, the second light-emitting layer, and the third light-emitting layer may each be stacked in two or more layers in each sub-pixel.

The display device according to various embodiments of this present disclosure may further include a color filter on the organic layer, and a black matrix positioned at the boundary between adjacent sub-pixels between the organic layer and the color filter, wherein the black matrix may have a width smaller than a width of the first bank.

In the display device according to various embodiments of this present disclosure, the black matrix may have an edge that is closer to the boundary between adjacent sub-pixels than an edge of the first bank.

The display device according to various embodiments of this present disclosure may further include a touch layer between the organic layer and the color filter, wherein the touch layer may include a bridge electrode and a sensor electrode on the bridge electrode, and the black matrix may overlap the bridge electrode and the sensor electrode.

The display device according to various embodiments of this present disclosure may further include a first transistor between the substrate and the first electrode, and a second transistor between the first transistor and the first electrode, wherein the first and second transistors may include a semiconductor layer, with the semiconductor layer of the first transistor including polysilicon and the semiconductor layer of the second transistor including oxide.

A display device according to various embodiments of this present disclosure includes a substrate, a display area including a plurality of sub-pixels, a non-display area outside the display area, a first electrode arranged on the substrate for each of the sub-pixels, a first bank arranged on the first electrode, located at a boundary between adjacent sub-pixels, and overlapping a peripheral region of an upper surface of the first electrode, and a plurality of nanostructures disposed on an upper surface of the first bank, wherein the plurality of nanostructures have a tilt angle equal to or less than 30 degrees with respect to a front of the display device, scattering or reflecting light incident the front and dissipating the light.

The display device according to various embodiments of this present disclosure may further include a second bank on the first bank, wherein the first bank may have an optical density greater than an optical density of the second bank, the first bank may include a black bank, and the second bank including a transparent bank.

In the display device according to various embodiments of this present disclosure, the plurality of nanostructures may have a surface height greater than or less than a surface height of the second bank.

The embodiments of this present disclosure are advantageous in terms of improving external light reflection by disposing a first bank including a black-colored material.

The embodiments of this present disclosure are advantageous in terms of improving surface reflection caused by external light by absorbing external light through a plurality of nanostructures disposed on an upper surface of the first bank.

The embodiments of this present disclosure are advantageous in terms of improving surface reflection caused by external light by arranging the nanostructures at an angle relative to the front, allowing the nanostructures to better absorb external light, or reflect or scatter the light downward, inducing absorption by adjacent nanostructures.

The embodiments of this present disclosure are advantageous in terms of facilitating implementation of a low-power, low-reflection display device by improving surface reflection of external light.

The embodiments of this present disclosure are advantageous in terms of facilitating application to foldable products with a folding display area by improving flexibility in such a way as to omit a polarizing part. However, the effects achievable through this present disclosure are not limited to the aforementioned, and additional effects not explicitly described herein may be readily understood by those skilled in the art based on the disclosure.

Although embodiments of this invention have been described above with reference to the accompanying drawings, it will be understood that the technical configuration of the invention described above can be implemented in other specific forms by those skilled in the art without changing the technical concept or essential features of the present invention. Therefore, it should be understood that the embodiments described above are examples and not limited in all respects. Furthermore, the scope of the present invention is defined by the claims set forth below and their equivalents, rather than the detailed description above. In addition, it should be understood that all modifications or variations derived from the meaning and scope of the claims and their equivalent concept are included within the scope of the this invention.

What is claimed is:

1. A display device, comprising:
a substrate;
a display area including a plurality of sub-pixels;
a non-display area outside the display area;
a first electrode arranged on the substrate for each of the sub-pixels;
a first bank arranged on the first electrode, located at a boundary between adjacent sub-pixels, and overlapping a peripheral region of an upper surface of the first electrode; and
a plurality of nanostructures disposed on an upper surface of the first bank.

2. The display device of claim 1, wherein the first bank comprises a black-colored material.

3. The display device of claim 1, further comprising a second bank on the first bank,
wherein the first bank has an optical density greater than an optical density of the second bank.

4. The display device of claim 3, wherein the first bank comprises a black bank, and the second bank comprises a transparent bank.

5. The display device of claim 3, wherein the plurality of nanostructures have a surface height greater than a surface height of the second bank.

6. The display device of claim 3, wherein the plurality of nanostructures have a surface height lower than a surface height of the second bank.

7. The display device of claim 1, wherein the plurality of nanostructures have a tilt angle equal to or less than 30 degrees with respect to a front of the display device.

8. The display device of claim 1, wherein the plurality of nanostructures comprise nanowires, nanotubes, or a micro-porous structure.

9. The display device of claim 1, wherein the plurality of nanostructures comprise a metal oxide or an organic material.

10. The display device of claim 1, wherein the plurality of nanostructures are directly arranged on the upper surface of the first bank.

11. The display device of claim 1, further comprising an organic layer disposed on the first electrode, wherein the plurality of sub-pixels comprise a first sub-pixel, a second sub-pixel, and a third sub-pixel, and the organic layer is arranged across the first sub-pixel to the third sub-pixel.

12. The display device of claim 11, wherein the organic layer constitutes a first light-emitting layer in the first sub-pixel, a second light-emitting layer in the second sub-pixel, and a third light-emitting layer in the third sub-pixel.

13. The display device of claim 12, wherein the first light-emitting layer, the second light-emitting layer, and the third light-emitting layer are each stacked in two or more layers in each sub-pixel.

14. The display device of claim 12, further comprising a color filter on the organic layer, and a black matrix positioned at the boundary between adjacent sub-pixels between the organic layer and the color filter,
wherein the black matrix has a width smaller than a width of the first bank.

15. The display device of claim 14, wherein the black matrix has an edge that is closer to the boundary between adjacent sub-pixels than an edge of the first bank.

16. The display device of claim 14, further comprising a touch layer between the organic layer and the color filter, wherein the touch layer comprises a bridge electrode and a sensor electrode on the bridge electrode, and the black matrix overlaps the bridge electrode and the sensor electrode.

17. The display device of claim 1, further comprising a first transistor between the substrate and the first electrode, and a second transistor between the first transistor and the first electrode,
wherein the first and second transistors comprise a semiconductor layer, with the semiconductor layer of the first transistor including polysilicon and the semiconductor layer of the second transistor including oxide.

18. A display device, comprising:
a substrate;
a display area including a plurality of sub-pixels;
a non-display area outside the display area;
a first electrode arranged on the substrate for each of the sub-pixels;
a first bank arranged on the first electrode, located at a boundary between adjacent sub-pixels, and overlapping a peripheral region of an upper surface of the first electrode; and
a plurality of nanostructures disposed on an upper surface of the first bank,
wherein the plurality of nanostructures have a tilt angle equal to or less than 30 degrees with respect to a front of the display device, scattering or reflecting light incident the front and dissipating the light.

19. The display device of claim 18, further comprising a second bank on the first bank, wherein the first bank has an optical density greater than an optical density of the second bank, the first bank comprising a black bank, and the second bank comprising a transparent bank.

20. The display device of claim 19, wherein the plurality of nanostructures have a surface height greater than or less than a surface height of the second bank.
